(19) United States
(12) Patent Application Publication
(10) Pub. No.: US 2025/0291215 A1
(43) Pub. Date: Sep. 18, 2025

(54) CIRCUIT BOARD AND METHOD FOR MANUFACTURING THE SAME, LIGHT-EMITTING SUBSTRATE, BACKLIGHT MODULE, DISPLAY PANEL AND DISPLAY APPARATUS

(71) Applicant: BOE Technology Group Co., Ltd., Beijing (CN)

(72) Inventors: Nianqi YAO, Beijing (CN); Kun ZHAO, Beijing (CN); Guangcai YUAN, Beijing (CN); Ce NING, Beijing (CN); Zhengliang LI, Beijing (CN); Zhanfeng CAO, Beijing (CN); Jiaxiang ZHANG, Beijing (CN); Qi QI, Beijing (CN)

(73) Assignee: BOE Technology Group Co., Ltd., Beijing (CN)

(21) Appl. No.: 18/862,965

(22) PCT Filed: Dec. 26, 2023
(86) PCT No.: PCT/CN2023/141888

§ 371 Date: Nov. 5, 2024

(30) Foreign Application Priority Data
Jan. 3, 2023 (CN) 202310002150.5

(51) Int. Cl. G02F 1/1335; G02F 1/13357; H05K 1/02; H05K 1/11; H05K 3/28

(52) U.S. Cl. CPC G02F 1/133612; G02F 1/133605; H05K 1/0298; H05K 1/111; H05K 3/282; H05K 2203/1377

(57) ABSTRACT

A circuit board includes a base substrate and an electrical pattern. The electrical pattern is arranged on the base substrate and includes a plurality of conductive patterns and a plurality of connection pads. Each conductive pattern is electrically connected to at least one connection pad. The electrical pattern is composed of a first conductive layer and/or a second conductive layer, wherein the second conductive layer covers a side of the first conductive layer away from the base substrate and two sides of the first conductive layer in the extension direction thereof. The electrical pattern further includes at least one of a first protective layer and a second protective layer, wherein the first protective layer and the second protective layer are used for improving the oxidation resistance of the electrical pattern. Either of the first protective layer and the second protective layer can form a second intermetallic compound with solder.

### CROSS-REFERENCE TO RELATED APPLICATIONS

This application is a national phase entry under 35 USC 371 of International Patent Application No. PCT/CN2023/141888, filed on Dec. 26, 2023, which claims priority to Chinese Patent Application No. 202310002150.5, filed on Jan. 3, 2023, each are incorporated herein by reference in their entirety.

### TECHNICAL FIELD

The present disclosure relates to the field of display technologies, and in particular, to a circuit board and a method for manufacturing the same, a light-emitting substrate, a backlight module, a display panel and display apparatuses.

### BACKGROUND

With the development of the light-emitting diode technologies, backlight sources using light-emitting diodes (LEDs) with sub-millimeter (micro) scale and even micrometer (mini) scale have been widely used. Therefore, not only may an image contrast of a product, such as a liquid crystal display (LCD), using the backlight source reach a level of an organic light-emitting diode (OLED) display product, but also the product may retain technical advantages of liquid crystal display, thereby improving an display effect of an image and providing users with a good visual experience.

### SUMMARY

In an aspect, a circuit board is provided. The circuit board includes: a base substrate and an electrical pattern. The electrical pattern is disposed on the base substrate. The electrical pattern includes a plurality of conductive patterns and a plurality of connection pads. A conductive pattern is electrically connected to at least one connection pad, and the connection pad is used to be connected to an electronic component. The electrical pattern is composed of at least one of a first conductive layer and a second conductive layer. The second conductive layer covers a surface of the first conductive layer away from the base substrate and two sides of the first conductive layer along an extension direction of the first conductive layer. The first conductive layer includes a first main material layer, a material of the first main material layer includes copper, and the first main material layer is capable of forming a first intermetallic compound with solder.

The electrical pattern includes: at least one of a first protective layer and a second protective layer. The first protective layer is included in the first conductive layer, and the first protective layer is disposed on a side of the first main material layer away from the base substrate. The second protective layer is included in the second conductive layer. The first protective layer and the second protective layer are used to enhance oxidation resistance of the electrical pattern. Any of the first protective layer and the second protective layer is capable of forming a second intermetallic compound with the solder.

In some embodiments, the first conductive layer further includes: at least one additional layer disposed between the first main material layer and the base substrate. The additional layer includes a second main material layer and a first stop layer that are stacked in a first direction. The first direction is a direction perpendicular to the base substrate and from the base substrate towards the first conductive layer. A material of the second main material layer includes copper, and the second main material layer is capable of forming a first intermetallic compound with the solder. The first stop layer is capable of forming a third intermetallic compound with the solder, and a reaction rate between the first stop layer and the solder is less than a reaction rate between the second main material layer and the solder.

In some embodiments, the second conductive layer further includes: a third main material layer and a second stop layer. The second stop layer, the third main material layer and the second protective layer are sequentially stacked in a first direction. The first direction is a direction perpendicular to the base substrate and from the base substrate towards the first conductive layer. A material of the third main material layer includes copper, and the third main material layer is capable of forming a first intermetallic compound with the solder. The second stop layer is capable of forming a fourth intermetallic compound with the solder, and a reaction rate between the second stop layer and the solder is less than a reaction rate between the third main material layer and the solder.

In some embodiments, the second conductive layer includes a first covering area and a second covering area that are connected. An orthographic projection of the first covering area on the base substrate covers an orthographic projection of the first conductive layer on the base substrate, and an orthographic projection of the second covering area on the base substrate is located on a side of the orthographic projection of the first conductive layer on the base substrate along the extension direction of the first conductive layer. A distance between a side surface of the second covering area away from the first conductive layer and the first conductive layer is greater than or equal to 2 μm.

In some embodiments, the first conductive layer further includes an adhesive layer, and the adhesive layer is disposed on a side of the first main material layer proximate to the base substrate.

In some embodiments, a material of the adhesive layer includes any of molybdenum-nickel-titanium, molybdenum-niobium alloy, molybdenum, titanium, molybdenum-titanium alloy, molybdenum-tungsten alloy and molybdenum-tantalum alloy.

In some embodiments, in a case where the electrical pattern includes a first stop layer, a second stop layer and an adhesive layer, a material of the first protective layer, a material of the second protective layer, a material of the first stop layer, a material of the second stop layer and a material of the adhesive layer each include any of nickel and nickel alloys.

In some embodiments, the nickel alloys include an (n+1) element alloy by doping nickel with any n kinds of tungsten, vanadium, aluminum, copper, lanthanum, lead, cobalt, silver, antimony, indium, gallium, zinc, tantalum, ruthenium, titanium, bismuth, neodymium, chromium, molybdenum, yttrium, iron, manganese, silicon, gold, niobium, boron, gadolinium, cerium, calcium, magnesium, hafnium, zirconium, palladium, germanium and tin, wherein n is a positive integer greater than or equal to 1.

In some embodiments, in the nickel alloys, a percentage of nickel atomics in a nickel-copper alloy is greater than or equal to 10%, and a percentage of nickel atomics in remaining nickel alloys is greater than or equal to 40%.

In some embodiments, in a case where the electrical pattern includes a second main material layer and a third main material layer, a sum of dimensions of the first main material layer, the second main material layer and the third main material layer in a first direction is in a range of 1 μm to 15 μm, inclusive; and a dimension of any of the first main material layer, the second main material layer and the third main material layer in the first direction is in a range of 1 μm to 10 μm, inclusive.

In a case where the electrical pattern includes a first stop layer, a second stop layer and an adhesive layer, and a material of the adhesive layer includes any of nickel and nickel alloys, a sum of dimensions of the first stop layer, the second stop layer, the adhesive layer, the first protective layer and the second protective layer in the first direction is in a range of 0.02 μm to 2 μm, inclusive; and a dimension of any of the first stop layer, the second stop layer, the adhesive layer, the first protective layer and the second protective layer in the first direction is in a range of 100 Å to 10000 Å, inclusive.

In a case where the material of the adhesive layer includes any of molybdenum-nickel-titanium alloy, molybdenum-niobium alloy, molybdenum, titanium, molybdenum-titanium alloy, molybdenum-tungsten alloy and molybdenum-tantalum alloy, a dimension of the adhesive layer in the first direction is in a range of 200 Å to 1000 Å, inclusive. The first direction is a direction perpendicular to the base substrate and from the base substrate towards the first conductive layer.

In some embodiments, the first main material layer includes: a seed layer and a growth layer that are stacked in a first direction. The first direction is a direction perpendicular to the base substrate and from the base substrate towards the first conductive layer. A dimension of the seed layer in the first direction is in a range of 1000 Å to 9000 Å, inclusive. A dimension of the growth layer in the first direction is in a range of 2 μm to 15 μm, inclusive.

In some embodiments, the circuit board further includes a reverse stress layer located between the base substrate and the first conductive layer, and a material of the reverse stress layer includes any of silicon nitride and silicon oxide.

In some embodiments, the circuit board has a plurality of edges. The circuit board has a device area and at least one bonding area, and the bonding area is closer to any edge of the circuit board than the device area. The plurality of connection pads are divided into a plurality of device connection pads and a plurality of chip connection pads. The plurality of device connection pads are located in the device area, and the plurality of chip connection pads are located in the bonding area.

In another aspect, a method for manufacturing a circuit board is provided. The method includes: providing a base substrate; forming a first initial conductive layer on a side of the base substrate, the first initial conductive layer including a first initial main material layer and/or a first initial protective layer; forming a first conductive layer, including: forming the first conductive layer from the first initial conductive layer using a single patterning process, the first initial main material layer forming a first main material layer, and the first initial protective layer forming a first protective layer; forming a second initial conductive layer on a side of the first conductive layer away from the base substrate, the second initial conductive layer including a second initial protective layer; and forming a second conductive layer, including: form the second conductive layer from the second initial conductive layer using a single patterning process, the second initial protective layer forming a second protective layer.

In yet another aspect, a light-emitting substrate is provided. The light-emitting substrate includes the circuit board as described in any of the above embodiments. The light-emitting substrate further includes an electronic component. Pins of the electronic component are electrically connected to connection pads of the circuit board by solder.

In some embodiments, the light-emitting substrate further includes a reflective layer. The reflective layer is disposed on a side of the electrical pattern away from the base substrate. The reflective layer is provided with a plurality of openings therein, and the pins of the electronic component are electrically connected to the solder and the connection pads through openings.

In yet another aspect, a backlight module is provided. The backlight module includes the light-emitting substrate as described in any of the above embodiments. The light-emitting substrate has a light-exit side and a non-light-exit side that are opposite. The backlight module further includes a plurality of optical films disposed on the light-exit side of the light-emitting substrate.

In yet another aspect, a display apparatus is provided. The display apparatus includes the display module as described in any of the above embodiments. The display apparatus further includes a liquid crystal display panel connected to the backlight module.

In yet another aspect, a display panel is provided. The display panel includes the light-emitting substrate as described in any of the above embodiments.

In yet another aspect, a display apparatus is provided. The display apparatus includes the display module as described in any of the above embodiments.

### BRIEF DESCRIPTION OF THE DRAWINGS

In order to describe technical solutions in the present disclosure more clearly, accompanying drawings to be used in some embodiments of the present disclosure will be introduced briefly below. Obviously, the accompanying drawings to be described below are merely accompanying drawings of some embodiments of the present disclosure, and a person of ordinary skill in the art may obtain other drawings according to these drawings. In addition, the accompanying drawings to be described below may be regarded as schematic diagrams, but are not limitations on an actual size of a product, an actual process of a method and an actual timing of a signal to which the embodiments of the present disclosure relate.

FIG. 1 is a structural diagram of a light-emitting substrate, in accordance with some embodiments;

FIG. 2A is a structural diagram of a circuit board, in accordance with some embodiments of the present disclosure;

FIG. 2B is a structural diagram of another circuit board, in accordance with some embodiments of the present disclosure;

FIG. 3A is a sectional view showing a structure of a circuit board, in accordance with some embodiments of the present disclosure;

FIG. 3B is a scanning electron microscope image of a circuit board, in accordance with some embodiments of the present disclosure;

FIG. 3C is a scanning electron microscope image of another circuit board, in accordance with some embodiments of the present disclosure;

FIG. 3D is a sectional view showing a structure of another circuit board, in accordance with some embodiments of the present disclosure;

FIG. 3E is a scanning electron microscope image of another circuit board, in accordance with some embodiments of the present disclosure;

FIG. 4 is a sectional view showing a structure of another circuit board, in accordance with some embodiments of the present disclosure;

FIG. 5A is a sectional view showing a structure of another circuit board, in accordance with some embodiments of the present disclosure;

FIG. 5B is a scanning electron microscope image of another circuit board, in accordance with some embodiments of the present disclosure;

FIG. 6 is a sectional view showing a structure of another circuit board, in accordance with some embodiments of the present disclosure;

FIG. 7 is a scanning electron microscope image of a light-emitting substrate, in accordance with some embodiments of the present disclosure;

FIG. 8 is an enlarged view of the scanning electron microscope image of the light-emitting substrate provided in FIG. 7 at a region C;

FIG. 9A is a sectional view showing a structure of another circuit board, in accordance with some embodiments of the present disclosure;

FIG. 9B is a scanning electron microscope image of another circuit board, in accordance with some embodiments of the present disclosure;

FIG. 10 is a curve graph of reflectivity of an copper alloy, in accordance with some embodiments;

FIG. 11 is a curve graph of reflectivity of a nickel alloy, in accordance with some embodiments of the present disclosure;

FIG. 12 is a sectional view showing a structure of another circuit board, in accordance with some embodiments of the present disclosure;

FIG. 13 is a flowchart of a method for manufacturing a circuit board, in accordance with some embodiments of the present disclosure;

FIGS. 14 to 19 are diagrams showing steps of a method for manufacturing a circuit board, in accordance with some embodiments of the present disclosure;

FIG. 20 is a structural diagram of a light-emitting substrate, in accordance with some embodiments of the present disclosure;

FIG. 21 is a structural diagram of a backlight module, in accordance with some embodiments of the present disclosure;

FIG. 22 is a structural diagram of a display apparatus, in accordance with some embodiments of the present disclosure;

FIG. 23 is a structural diagram of a display panel, in accordance with some embodiments of the present disclosure; and

FIG. 24 is a structural diagram of another display apparatus, in accordance with some embodiments of the present disclosure.

### DETAILED DESCRIPTION

Technical solutions in some embodiments of the present disclosure will be described clearly and completely with reference to the accompanying drawings below. Obviously, the described embodiments are merely some but not all embodiments of the present disclosure. All other embodiments obtained by a person of ordinary skill in the art based on the embodiments of the present disclosure shall be included in the protection scope of the present disclosure.

Unless the context requires otherwise, throughout the description and the claims, the term “comprise” is construed as open and inclusive, i.e., “including, but not limited to”. In the description of the specification, the terms such as “one embodiment”, “some embodiments”, “exemplary embodiments”, “example” or “some examples” are intended to indicate that specific features, structures, materials or characteristics related to the embodiment(s) or example(s) are included in at least one embodiment or example of the present disclosure. Schematic representations of the above terms do not necessarily refer to the same embodiment(s) or example(s). In addition, the specific features, structures, materials, or characteristics described herein may be included in any one or more embodiments or examples in any suitable manner.

Hereinafter, the terms such as “first” and “second” are used for descriptive purposes only, and are not to be construed as indicating or implying the relative importance or implicitly indicating the number of indicated technical features. Thus, features defined with “first” or “second” may explicitly or implicitly include one or more of the features. In the description of the embodiments of the present disclosure, the term “a plurality of” or “the plurality of” means two or more unless otherwise specified.

In the description of some embodiments, the expressions “coupled” and “connected” and derivatives thereof may be used. The term “connection” should be understood in a broad sense. For example, the “connection” may be a fixed connection, a detachable connection, or of an integrated structure; it may be a direct connection or an indirect connection by an intermediate medium. The term “coupled” indicates, for example, that two or more components are in direct physical or electrical contact. However, the term “coupled” or “communicatively coupled” may also mean that two or more components are not in direct contact with each other, but still cooperate or interact with each other. The embodiments disclosed herein are not necessarily limited to the content herein.

The phrase “at least one of A, B and C” has a same meaning as the phrase “at least one of A, B or C”, and they both include the following combinations of A, B and C: only A, only B, only C, a combination of A and B, a combination of A and C, a combination of B and C, and a combination of A, B and C.

The phrase “A and/or B” includes the following three combinations: only A, only B, and a combination of A and B.

The term such as “parallel”, “perpendicular” or “equal” as used herein includes a stated condition and a condition similar to the stated condition. A range of the similar condition is within an acceptable range of deviation. The acceptable range of deviation is determined by a person of ordinary skill in the art in view of measurement in question and errors associated with the measurement of a particular quantity (i.e., limitations of the measurement system). For example, the term “parallel” includes absolute parallelism and approximate parallelism, and an acceptable range of deviation of the approximate parallelism may be a deviation within 5°; the term “perpendicular” includes absolute perpendicularity and approximate perpendicularity, and an acceptable range of deviation of the approximate perpendicularity may also be a deviation within 5°; and the term “equal” includes absolute equality and approximate equality, and an acceptable range of deviation of the approximate equality may be a difference between two equals being less than or equal to 5% of either of the two equals.

It will be understood that when a layer or element is referred to as being on another layer or substrate, the layer or element may be directly on the another layer or substrate, or there may be intermediate layer(s) between the layer or element and the another layer or substrate.

Exemplary embodiments are described herein with reference to sectional views and/or plane views as idealized exemplary drawings. In the accompanying drawings, thicknesses of layers and sizes of areas/regions are enlarged for clarity. Variations in shapes relative to the accompanying drawings due to, for example, manufacturing technologies and/or tolerances may be envisaged. Therefore, the exemplary embodiments should not be construed to be limited to the shapes of areas/regions shown herein, but to include deviations in the shapes due to, for example, manufacturing. For example, an etched area/region shown in a rectangular shape generally has a feature of being curved. Therefore, the areas/regions shown in the accompanying drawings are schematic in nature, and their shapes are not intended to show actual shapes of the areas/regions in an apparatus, and are not intended to limit the scope of the exemplary embodiments.

Currently, mini light-emitting diodes (mini-LEDs) and micro light-emitting diodes (micro-LEDs) have many advantages in terms of both backlight and direct display.

For example, the mini-LED is a light-emitting diode (LED) with a size greater than or equal to 80 μm and less than 200 μm. The micro-LED is a LED with a size less than 100 μm. In some examples, the size of the micro-LED may be less than or equal to 50 μm.

For backlight applications, a plurality of micro-LEDs are arranged in a matrix and are combined with local dimming technology, so that a good brightness uniformity and a high color contrast may be achieved within a small light mixing distance, thereby achieving ultra-thin, high color rendering index, high contrast and high brightness of the terminal product, which is superior to traditional direct-type or edge-type backlight architectures. In addition, the plurality of micro-LEDs may be disposed on a flexible substrate and combined with a passive display panel with a curved surface, so that a curved display similar to that achieved by an organic light-emitting diode technology may be achieved under a condition that the image quality is ensured.

However, the mini-LED and micro-LED products have the following two main problems that lead to the high costs: first, relatively poor oxidation resistance leading to a need for antioxidant treatment; second, an influence of structural design leading to a lot of mask processes during manufacture.

For the problems of the poor oxidation resistance and the high cost caused by the poor oxidation resistance, surface mounted technology (SMT) is usually used in the mini-LED and micro-LED products. The SMT is a common technology and process in the electronics assembly industry, and is a technology that electronic components with pins are placed on a surface of a base substrate with circuits and connection pads (also known as pads), and perform soldering assembly by reflow soldering, dip soldering or other method. In order to complete fixed connection between the electronic component and the connection pad, it is necessary to provide solder on the connection pad to be electrically connected to the electronic component on the base substrate or to provide solder on the pin of the electronic component, and then make the electronic component and the connection pad aligned and be in contact, for example, at a high temperature of 230° C. to 260° C., so that the solder melts and obtains good wetting, and then quickly cools down to achieve fixed connection or soldering between the electronic component and the connection pad.

Since the material of the connection pad is generally copper, and copper is prone to oxidize, a surface treatment need to be performed on the connection pad to prevent oxidation of copper. The surface treatment methods for the connection pads include: electroless nickel/immersion gold, organic solderability preservatives (OSP), forming a copper alloy layer and the like. The electroless nickel/immersion gold and the OSP have high cost consumption and serious environmental pollution, and it is difficult to mass production, while the copper alloy layer has weak oxidation resistance and is prone to be oxidized, resulting in reduced yield.

For the problems of the high cost caused by the influence of structural design, mini-LED backlight products and micro-LED backlight products mainly have printed circuit board (PCB) bases and glass bases. Compared with the PCB base, the glass base has high manufacturing accuracy, good heat dissipation, low warping, and ultra-thinness, and other advantages.

However, in the related art, due to the structural characteristics of glass-based mini-LED products and micro-LED products, the costs are relatively high.

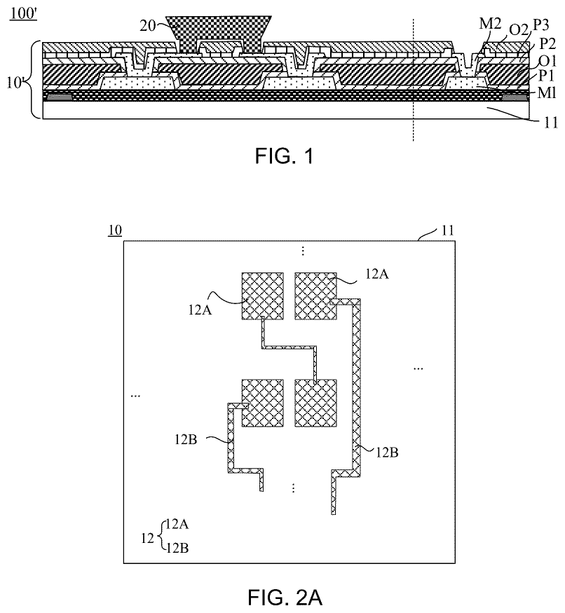

For example, as shown in FIG. 1, a light-emitting substrate 100′ includes a circuit board 10′ and an electronic component 20 connected onto the circuit board 10′. For example, the light-emitting component 20 includes a mini-LED or a micro-LED.

The circuit board 10′ includes a base substrate 11, and a first conductive structure layer M1 and a second conductive structure layer M2 that are disposed on the base substrate 11. The second conductive structure layer M2 is farther away from the base substrate 11 than the first conductive structure layer M1. The first conductive structure layer M1 and the second conductive structure layer M2 are located in different conductive layers, that is, each conductive layer needs to be formed through at least one mask process.

A first passivation layer P1, a first planarization layer O1 and a second passivation layer P2 are provided between the first conductive structure layer M1 and the second conductive structure layer M2. The second conductive structure layer M2 is connected to the first conductive structure layer M1 through a via hole extending through the first passivation layer P1, the first planarization layer O1 and the second passivation layer P2. A third passivation layer P3 and a second planarization layer O2 are provided on a side of the second conductive structure layer M2 away from the base substrate 11, and pins of the electronic component 20 are connected to the second conductive structure layer M2 through via holes extending through the third passivation layer P3 and the second planarization layer O2.

For example, a material of the base substrate 11 includes glass. Materials of the first passivation layer P1, the second passivation layer P2 and the third passivation layer P3 may be silicon nitride, silicon oxide, silicon oxynitride, or the like. Materials of the first planarization layer O1 and the second planarization layer O2 include organic films.

The above circuit board 10′ has more than one conductive structure layer, so that the manufacturing process of the circuit board is complicated, there are many patterning processes involved, resulting in high costs.

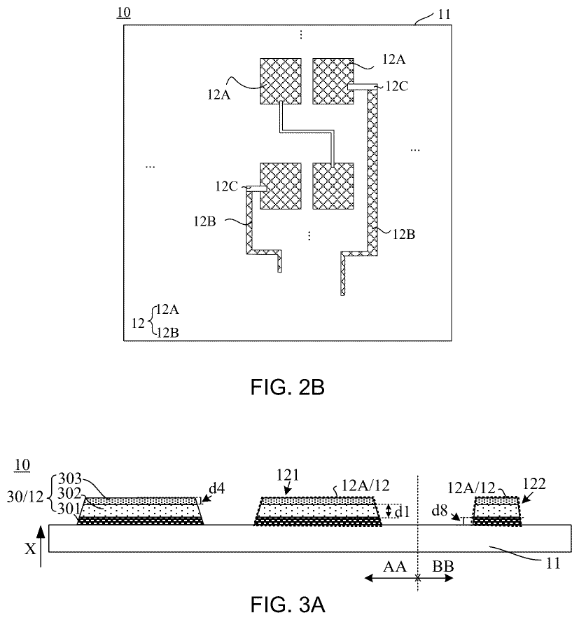

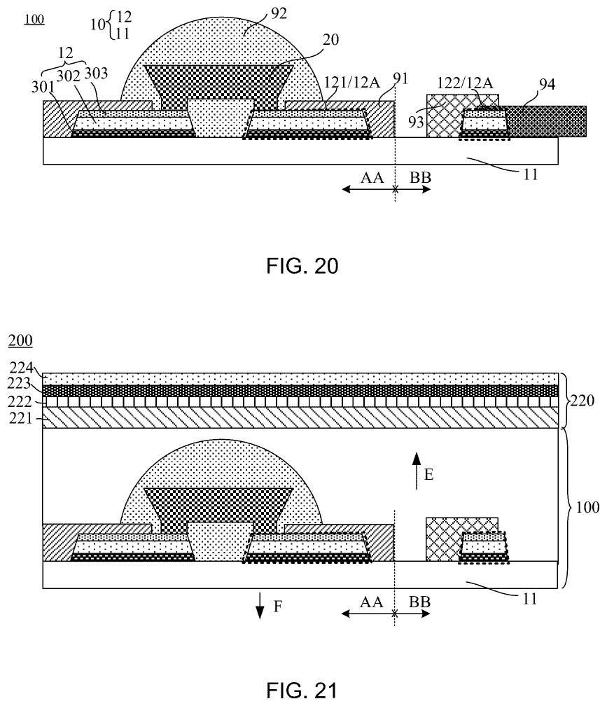

In light of this, as shown in FIGS. 2A to 4, some embodiments of the present disclosure provide a circuit board 10. The circuit board 10 includes a base substrate 11 and an electrical pattern 12. The electrical pattern 12 is disposed on the base substrate 11. As shown in FIGS. 2A and 2B, the electrical pattern 12 includes a plurality of conductive patterns 12B and a plurality of connection pads 12A. The conductive pattern 12B is electrically connected to at least one connection pad 12A. The connection pad 12A is used to be connected to the electronic component 20 (as shown in FIG. 20, and the same applies below).

In some examples, the base substrate 11 is a rigid substrate. In some other examples, the base substrate 11 is a flexible substrate. For example, a material of the base substrate 11 includes any of plastic, FR-4 grade material, resin, glass, quartz, polyimide, or polymethyl methacrylate (PMMA).

In the embodiments of the present disclosure, the circuit board 10 uses glass as the base substrate 11. For example, a glass substrate is alkali-free glass, alkali glass, reinforced glass or tempered glass.

In some examples, as shown in FIG. 2A, the conductive pattern 12B and the connection pad 12A are directly connected, and the connected conductive pattern 12B and connection pad 12A have an integral structure. A surface of the conductive pattern 12B away from the base substrate 11 will be covered by an insulating layer, while a surface of the connection pad 12A away from the base substrate 11 is exposed for being connected to the electronic component 20.

In some examples, as shown in FIG. 2B, the conductive pattern 12B and the connection pad 12A are spaced apart from each other, and the conductive pattern 12B and the connection pad 12A that are in a connection relationship are electrically connected by a bridge pattern 12C.

In the embodiments of the present disclosure, the electrical pattern 12 includes connection pads 12A and conductive patterns 12B. That is, a patterning process is no longer used to re-form the connection pads 12A on the electrical pattern 12, but after the electrical pattern 12 is formed, part of the electrical pattern 12 is directly formed as the connection pads 12A. The connection pad 12A is used to be connected to the electronic component 20, thereby achieving electrical connection between the electrical pattern 12 and the electronic component 20. The design of providing the connection pad 12A and the conductive pattern 12B in the same electrical pattern 12 may simplify the manufacturing process of the circuit board 10, reduce the number of masks, and reduce the cost of the circuit board 10.

For example, the conductive pattern 12B is used to transmit a signal, such as an analog electrical signal or a digital electrical signal.

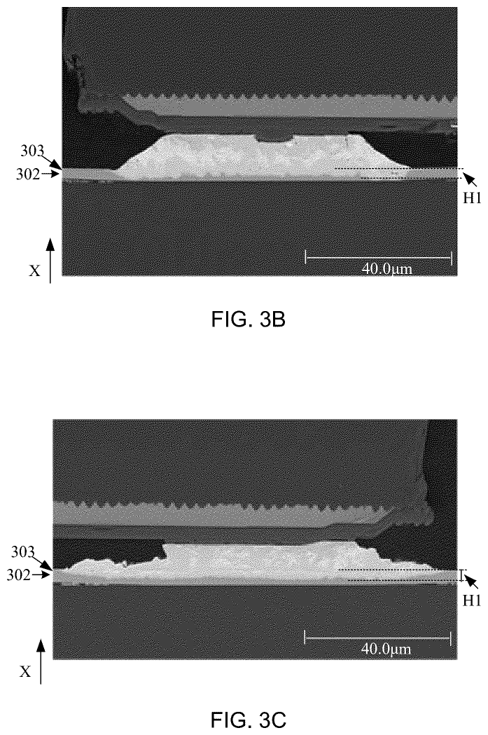

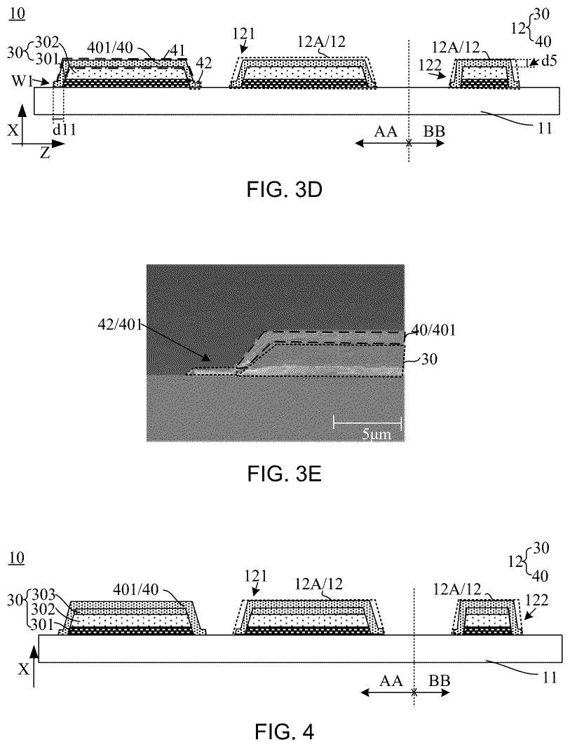

As shown in FIGS. 3A to 4, the electrical pattern 12 includes a first conductive layer 30 and/or a second conductive layer 40, and the second conductive layer 40 covers a surface of the first conductive layer 30 away from the base substrate 11 and two sides of the first conductive layer 30 along an extension direction thereof.

That is, the electrical pattern 12 includes the first conductive layer 30. The electrical pattern 12 may, while including the first conductive layer 30, include the second conductive layer 40 or not include the second conductive layer 40.

For example, as shown in FIG. 3A, the electrical pattern 12 includes a first conductive layer 30.

For example, as shown in FIGS. 3D and 4, the electrical pattern 12 includes a first conductive layer 30 and a second conductive layer 40.

That is, if the electrical pattern 12 includes the second conductive layer 40, the second conductive layer 40 wraps the first conductive layer 30.

As shown in FIGS. 3A to 4, the first conductive layer 30 includes a first main material layer 302. A material of the first main material layer 302 includes copper. The first main material layer 302 may form a first intermetallic compound with a solder.

For example, as shown in FIG. 3A, a dimension d1 of the first main material layer 302 in a first direction X is in a range of 1 μm to 10 μm, inclusive. That is, 1 μm≤d1≤10 μm. For example, the dimension d1 of the first main material layer 302 in the first direction X is 1 μm, 2 μm, 3 μm, 4 μm, 5 μm, 6 μm, 7 μm, 8 μm, 9 μm or 10 μm, which is not limited here. The first direction X is a direction perpendicular to the base substrate 11 and from the base substrate 11 towards the first conductive layer 30.

It will be noted that a compound formed by metal and metal or by metal and metalloid (e.g., H, B, N, S, P, C, Si) is referred to as an intermetallic compound (IMC). Elements in the intermetallic compound are bonded by metallic bonds to maintain metallic properties. The intermetallic compound is a product of an interfacial reaction.

The solder may include, for example, tin. Using the SMT, the pins of the electronic component 20 are connected to the connection pads 12A by solder, thereby achieving a fixed connection between the electronic component 20 and the connection pad 12A.

During soldering, copper (Cu) in the first main material layer 302 and tin (Sn) in the solder will form CuₓSn_{y} series “temporarily stable” intermetallic compounds, where in CuₓSn_{y}, x is equal to 3, 4, 5, or 6, and y is equal to 2, 3, 4, or 5. A thickness and a thickness ratio of these CuₓSn_{y} series intermetallic compounds will change with temperature, time, environment and usage conditions of the soldering process. The CuₓSn_{y} is a first intermetallic compound formed by the first main material layer 302 and the solder, thereby achieving the connection between the first main material layer 302 and the solder.

As shown in FIGS. 3A to 4, the electrical pattern 12 further includes at least one of a first protective layer 303 and a second protective layer 401. The first protective layer 303 is located in the first conductive layer 30. The first protective layer 303 is disposed on a side of the first main material layer 302 away from the base substrate 11. The second protective layer 401 is located in the second conductive layer 40. Any of the first protective layer 303 and the second protective layer 401 is used to improve the oxidation resistance of the electrical pattern 12.

For example, as shown in FIG. 3A, the electrical pattern 12 includes a first protective layer 303, and the first protective layer 303 may improve the oxidation resistance of the electrical pattern 12.

For example, as shown in FIG. 3A, a dimension d4 of the first protective layer 303 in the first direction X is in a range of 100 Å to 10000 Å, inclusive. For example, the dimension d4 of the first protective layer 303 in the first direction X is 100 Å, 200 Å, 800 Å, 1000 Å, 3000 Å, 5000 Å or 10000 Å, which is not limited here.

For example, as shown in FIG. 3D, the electrical pattern 12 includes a second protective layer 401, and the second protective layer 401 may improve the oxidation resistance of the electrical pattern 12. Furthermore, since the second protective layer 401 is located in the second conductive layer 40, the second protective layer 401 covers a surface of the first conductive layer 30 away from the base substrate 11 and two sides of the first conductive layer 30 along an extension direction thereof. Therefore, the second protective layer 401 may further improve the oxidation resistance of the side of the electrical pattern 12.

For example, as shown in FIG. 3D, a dimension d5 of the second protective layer 401 in the first direction X is in a range of 100 Å to 10000 Å, inclusive. For example, the dimension d5 of the second protective layer 401 in the first direction X is 100 Å, 400 Å, 600 Å, 800 Å, 1000 Å, 3000 Å or 10000 Å, which is not limited here.

For example, as shown in FIG. 4, the electrical pattern 12 includes a first protective layer 303 and a second protective layer 401. The first protective layer 303 and the second protective layer 401 may jointly improve the oxidation resistance of the electrical pattern 12. Similarly, the second protective layer 401 may further improve the oxidation resistance of the side of the electrical pattern 12.

For example, a material of the first protective layer 303 and a material of the second protective layer 401 each include any of nickel and nickel alloys. For example, the material of the first protective layer 303 is any of nickel and nickel alloys. The material of the second protective layer 401 is any of nickel and nickel alloys.

For example, the nickel alloys include an (n+1) element alloy by doping nickel (Ni) with any n kinds of tungsten (W), vanadium (V), aluminum (Al), copper (Cu), lanthanum (La), lead (Pb), cobalt (Co), silver (Ag), antimony (Sb), indium (In), gallium (Ga), zinc (Zn), tantalum (Ta), ruthenium (Ru), titanium (Ti), bismuth (Bi), neodymium (Nd), chromium (Cr), molybdenum (Mo), yttrium (Y), iron (Fe), manganese (Mn), silicon (Si), gold (Au), niobium (Nb), boron (B), gadolinium (Gd), cerium (Ce), calcium (Ca), magnesium (Mg), hafnium (Hf), zirconium (Zr), palladium (Pd), germanium (Ge) and tin (Sn), wherein n is a positive integer greater than or equal to 1.

In a case of n=1, the nickel alloy is a binary alloy formed by doping nickel (Ni) with one metal, such as a NiW binary alloy by doping nickel (Ni) with tungsten (W), a NiV binary alloy by doping nickel (Ni) with vanadium (V), a NiAl binary alloy by doping nickel (Ni) with aluminum (Al), or a NiCu binary alloy by doping nickel (Ni) with copper (Cu).

In a case of n=2, the nickel alloy is a ternary alloy formed by doping nickel (Ni) with two metals, such as a NiVAl ternary alloy by doping nickel (Ni) with vanadium (V) and aluminum (Al).

In a case of n≥3, the nickel alloy may be called a multi-element alloy by doping nickel (Ni) with multiple metals.

It will be noted that the material of the first protective layer 303 and the material of the second protective layer 401 may be the same or different, and there is no limitation thereto.

Nickel and nickel alloys have good oxidation resistance. Therefore, the material of the first protective layer 303 and the material of the second protective layer 401 each include any of nickel and nickel alloys, thereby effectively improving the oxidation resistance of the electrical pattern 12. Nickel and nickel alloys have good oxidation resistance, which can be characterized by reflectivity of the materials. Reference may be made to the subsequent contents, and details are not described in detail here.

The provision of the electrical pattern 12 including at least one of the first protective layer 303 and the second protective layer 401 may avoid using electroless nickel/immersion gold, OSP, forming a copper alloy layer and other surface treatment method to treat the electrical pattern 12, thereby reducing the cost consumption while the electrical pattern 12 is ensured to have good oxidation resistance.

As shown in FIGS. 3A to 4, any of the first protective layer 303 and the second protective layer 401 may form a second intermetallic compound with the solder.

That is, the first protective layer 303 and the solder may form a second intermetallic compound, the second protective layer 401 and the solder may form a second intermetallic compound, and in a case where both the first protective layer 303 and the second protective layer 401 exist, the first protective layer 303 and the second protective layer 401 may form a second intermetallic compound together with the solder. Therefore, existence of the first protective layer 303 and the second protective layer 401 does not hinder the connection between the pins of the electronic component 20 and the connection pads 12A, but may achieve the connection between the pins of the electronic component 20 and the connection pads 12A.

For example, in the circuit board 10 shown in FIG. 3A, the electrical pattern 12 includes a first conductive layer 30, and the first conductive layer 30 includes a first main material layer 302 and a first protective layer 303 that are disposed in the first direction X. As shown in FIGS. 3A and 3B, in a case where the dimension d4 of the first protective layer 303 in the first direction X is 200 Å, a reaction depth H1 of the first main material layer 302 and the first protective layer 303 with the solder is 2.5 μm. As shown in FIGS. 3A and 3C, in a case where the dimension d4 of the first protective layer 303 in the first direction X is 1000 Å, a reaction depth H1 of the first main material layer 302 and the first protective layer 303 with the solder is 1.5 μm.

Therefore, the existence of the first protective layer 303 does not hinder the connection between the pins of the electronic component 20 and the connection pads 12A. Moreover, thickening the first protective layer 303 may effectively prevent the solder from further reacting deep into the electrical pattern 12, that is, reduce the reaction between the solder and the first main material layer 302, thereby improving a repair yield rate.

For example, the material of the first protective layer 303 and the material of the second protective layer 401 include any of nickel and nickel alloys. During soldering, nickel (Ni) in the first protective layer 303 and tin (Sn) in the solder form a second intermetallic compound (e.g., including Ni₃Sn₄). Similarly, nickel (Ni) in the second protective layer 401 and tin (Sn) in the solder form a second intermetallic compound including Ni₃Sn₄.

Therefore, in a case where the connection pad 12A includes any of a first protective layer 303 and a second protective layer 401, in a process of soldering the pins of the electronic component 20 and the connection pad 12A using the solder, the solder and the first protective layer 303 (and/or the second protective layer 401) react to form a second intermetallic compound, and the solder and the first main material layer 302 form a first intermetallic compound, thereby achieving the soldering.

The electrical pattern 12 in the embodiments of the present disclosure includes the connection pads 12A and the conductive patterns 12B. The structure of the circuit board 10 may be simplified. Therefore, the manufacturing process of the circuit board 10 may be simplified, the number of the masks may be reduced, and the cost of the circuit board 10 may be reduced.

In addition, the provision of the electrical pattern 12 including at least one of the first protective layer 303 and the second protective layer 401 may enhance the oxidation resistance of the electrical pattern 12 and prolong the life of the electrical pattern 12. Furthermore, any of the first protective layer 303 and the second protective layer 401 may form a second intermetallic compound with the solder, so as to achieve soldering between the connection pads 12A of the electrical pattern 12 and the electronic component 20. In this way, not only may the costs be saved, but also the manufacture process of the circuit board 10 may be simplified. For an introduction to a method for manufacturing the circuit board 10, reference may be made to the subsequent contents, and details are not described in detail here.

In some embodiments, as shown in FIG. 3D, the second conductive layer 40 includes a first covering area 41 and a second covering area 42 that are connected. An orthographic projection of the first covering area 41 on the base substrate 11 covers an orthographic projection of the first conductive layer 30 on the base substrate 11, and an orthographic projection of the second covering area 42 on the base substrate 11 is located on a side of an orthographic projection of the first conductive layer 30 on the base substrate 11 along an extension direction thereof.

For example, the first covering area 41 and the second covering area 42 are of an integral structure.

For example, a distance d11 between a side surface W1 of the second covering area 42 away from the first conductive layer 30 and the first conductive layer 30 is greater than or equal to 2 μm. That is, in a second direction Z, the distance between the side surface W1 of the second covering area 42 away from the first conductive layer 30 and the first conductive layer 30 is greater than or equal to 2 μm. The first direction X is a direction perpendicular to the base substrate 11 and from the base substrate 11 towards the first conductive layer 30. The second direction Z is perpendicular to the first direction X and perpendicular to an extending direction of the first conductive layer 30.

For example, as shown in FIG. 3D, the second conductive layer 40 includes a second protective layer 401. The second protective layer 401 includes a first covering area 41 and a second covering area 42 connected to two sides of the first covering area 41. In the second direction Z, the distance d11 between the side surface W1 of the second covering area 42 away from the first conductive layer 30 and the first conductive layer 30 is equal to 2 μm.

It will be noted that contour edges at two sides of the first conductive layer 30 along the extension direction thereof are each provided in an oblique line. That is, a cross-section of the first conductive layer 30 along the extension direction thereof is in a shape of a trapezoid. The distance d11 between the side surface W1 of the second covering area 42 away from the first conductive layer 30 and the first conductive layer 30 may be a minimum distance, a maximum distance, or an average of the maximum distance and the minimum distance, which is not limited here.

The provision of the second conductive layer 40 including the first covering area 41 and the second covering area 42 may improve the oxidation resistance of the electrical pattern 12.

FIG. 3E is a scanning electron microscope image of the circuit board 10 shown in FIG. 3D. It can be seen from FIG. 3E that the first covering area 41 and the second covering area 42 of the second protective layer 401 have a good wrapping effect on the first conductive layer 30.

In the related art, during connecting the pins of the electronic component 20 to the connection pads 12A by solder, a depth of the intermetallic compound formed is usually in a range of 2 μm to 3 μm, inclusive. In a case where the thickness of the electrical pattern 12 is less than 3 μm, the connection pads 12A have a risk of forming the intermetallic compound completely. This will cause a decrease in adhesion between the connection pads 12A and the base substrate 11 and an increase in a risk of the connection pads 12A falling off, thereby reducing the product yield.

Therefore, in order to improve the product yield and meet the requirement of repeatedly soldering the pins of the electronic component 20, the thickness of the electrical pattern 12 may increase, and the thickness of the electrical pattern 12 may increase to, for example, 8 μm. However, in a process of forming the first main material layer 302 of the electrical pattern 12 through a conventional sputtering process, it is difficult for the first main material layer 302 formed through a single sputtering process to reach a thickness of more than 5 μm. Alternatively, the first main material layer 302 with a thickness of more than 8 μm may be formed through an electroplating process, but the process steps are relatively complicated.

Based on this, the present disclosure provides the following embodiments.

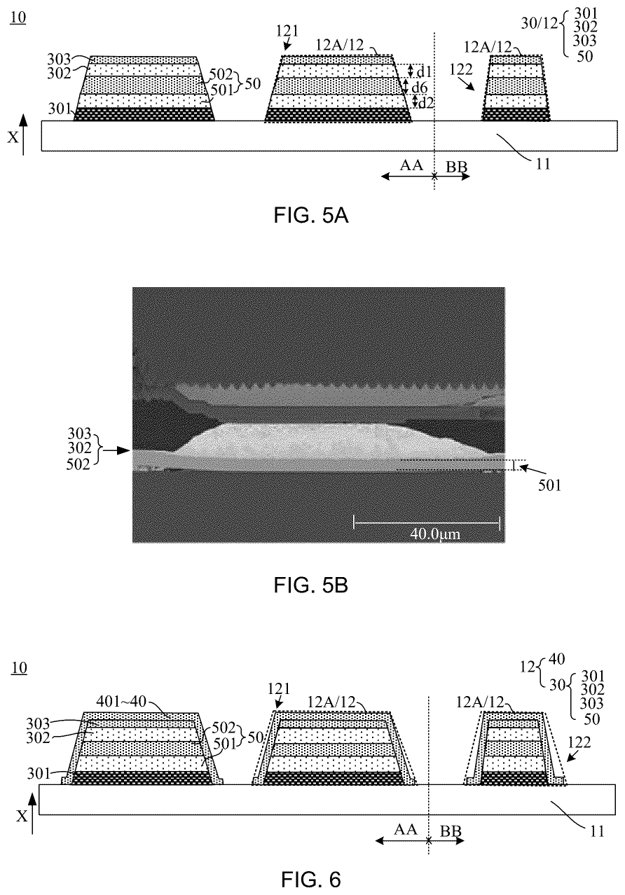

In some embodiments, as shown in FIGS. 5A and 6, the first conductive layer 30 further includes at least one additional layer 50 provided between the first main material layer 302 and the base substrate 11. The additional layer 50 includes a second main material layer 501 and a first stop layer 502 that are stacked in the first direction X. The first direction X is a direction perpendicular to the base substrate 11 and from the base substrate 11 towards the first conductive layer 30. A material of the second main material layer 501 includes copper, and the second main material layer 501 and the solder can form a first intermetallic compound. The first stop layer 502 and the solder can form a third intermetallic compound, and a reaction rate between the first stop layer 502 and the solder is less than a reaction rate between the second main material layer 501 and the solder.

For example, as shown in FIG. 5A, a dimension d2 of the second main material layer 501 in the first direction X is in a range of 1 μm to 10 μm, inclusive. That is, 1 μm≤d2≤10 μm. For example, the dimension d2 of the second main material layer 501 in the first direction X is 1 μm, 2 μm, 3 μm, 4 μm, 5 μm, 6 μm, 7 μm, 8 μm, 9 μm or 10 μm, which is not limited here.

For example, as shown in FIG. 5A, a dimension d6 of the first stop layer 502 in the first direction X is in a range of 100 Å to 10000 Å, inclusive. For example, the dimension d6 of the first stop layer 502 in the first direction X is 100 Å, 300 Å, 500 Å, 1000 Å, 5000 Å, 8000 Å or 10000 Å, which is not limited here.

In some examples, as shown in FIG. 5A, the first conductive layer 30 includes a single additional layer 50. That is, the electrical pattern 12 includes a second main material layer 501, a first stop layer 502, a first main material layer 302 and a first protective layer 303 that are sequentially provided in the first direction X.

By providing the at least one additional layer 50, in a case where the electrical pattern 12 includes a first main material layer 302, adding at least one second main material layer 501 may increase the thickness of the electrical pattern 12, thereby effectively reducing the risk of the connection pad 12A forming the intermetallic compound completely and reducing the risk of the connection pad 12A falling off.

Since the material of the second main material layer 501 includes copper, the copper in the second main material layer 501 and the tin in the solder may form a first intermetallic compound. The reaction rate between the first stop layer 502 and the solder is less than the reaction rate between the second main material layer 501 and the solder. It can also be understood that the reaction rate between the first stop layer 502 and the solder is less than a reaction rate between the first main material layer 302 and the solder.

For example, as shown in FIGS. 5A and 5B, in a process of soldering the pins of the electronic component 20 and the connection pads 12A using the solder, the solder and the first protective layer 303 form a second intermetallic compound, and then the solder and the first main material layer 302 form a first intermetallic compound. Since the reaction rate between the first stop layer 502 and the solder is less than the reaction rate between the second main material layer 501 (the first main material layer 302) and the solder, the first stop layer 502 may effectively prevent the solder from further reacting deep into the electrical pattern 12, that is, the first stop layer 502 may effectively prevent the solder from further reacting in a direction from the electrical pattern 12 towards the base substrate 11, so as to achieve a minor damage to the second main material layer 501, thereby reducing the risk of the connection pad 12A forming the intermetallic compound completely and effectively reducing the risk of the connection pad 12A falling off.

For example, a material of the first stop layer 502 includes any of nickel and nickel alloys.

For example, the nickel alloys include an (n+1) element alloy by doping nickel (Ni) with any n kinds of tungsten (W), vanadium (V), aluminum (Al), copper (Cu), lanthanum (La), lead (Pb), cobalt (Co), silver (Ag), antimony (Sb), indium (In), gallium (Ga), zinc (Zn), tantalum (Ta), ruthenium (Ru), titanium (Ti), bismuth (Bi), neodymium (Nd), chromium (Cr), molybdenum (Mo), yttrium (Y), iron (Fe), manganese (Mn), silicon (Si), gold (Au), niobium (Nb), boron (B), gadolinium (Gd), cerium (Ce), calcium (Ca), magnesium (Mg), hafnium (Hf), zirconium (Zr), palladium (Pd), germanium (Ge) and tin (Sn), wherein n is a positive integer greater than or equal to 1.

For an introduction to the value of n, reference may be made to the above contents, and details are not repeated here.

Since a reaction rate between the first stop layer 502 formed by any of nickel and nickel alloys and the solder is less than the reaction rate between the first main material layer 302 and the solder, the risk of the connection pad 12A forming the intermetallic compound completely may be reduced, and the risk of the connection pad 12A falling off may be effectively reduced.

The material of the first stop layer 502 includes any of nickel (Ni) and nickel alloys. It can also be understood that a reaction rate between nickel (Ni) in the nickel alloys and tin (Sn) in the solder is less than a reaction rate between copper (Cu) and tin (Sn) in the solder.

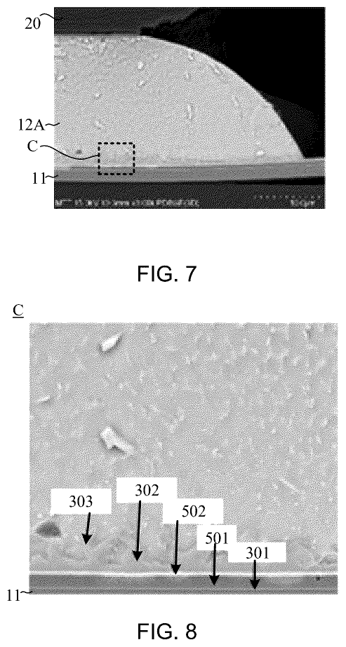

As shown in FIGS. 7 and 8, FIGS. 7 and 8 are each a scanning electron microscope image of a cross-section of a laminated structure after the pin of the electronic component 20 are connected to the connection pad 12A, and FIG. 8 is an enlarged view of a region C in FIG. 7. It can be seen from FIG. 8 that, the first stop layer 502 does not completely react with the solder to form the third intermetallic compound, thereby effectively preventing the connection pad 12A from completely forming the intermetallic compound.

It will be noted that the first protective layer 303 and the solder may form a second intermetallic compound, the second protective layer 401 and the solder may form a second intermetallic compound, and the first stop layer 502 and the solder may form a third intermetallic compound. Since the material of the first protective layer 303, the material of the second protective layer 401 and the material of the first stop layer 502 may each be any of nickel and nickel alloys. When the first protective layer 303, the second protective layer 401 and the first stop layer 502 react with tin (Sn) in the solder, it is actually a reaction between nickel (Ni) and tin (Sn) in the solder. Therefore, the second intermetallic compound and the third intermetallic compound may be the same intermetallic compound.

Therefore, the second intermetallic compound, the third intermetallic compound and a fourth intermetallic compound described below are names of intermetallic compounds formed by different film layers and the solder, which do not mean that their materials are different.

In some examples, as shown in FIG. 6, the first conductive layer 30 includes a single additional layer 50. The base substrate 11, the second main material layer 501, the first stop layer 502, the first main material layer 302, the first protective layer 303 and the second protective layer 401 are sequentially provided in the first direction X.

In a process of soldering the pins of the electronic component 20 and the connection pads 12A using the solder, the solder may form second intermetallic compounds with the second protective layer 401 and with the first protective layer 303, and then the solder and the first main material layer 302 form a first intermetallic compound. The first stop layer 502 may effectively prevent the solder from further reacting deep into the electrical pattern 12, thereby reducing the risk of the connection pad 12A forming the intermetallic compound completely and effectively reducing the risk of the connection pad 12A falling off.

In some other embodiments, there may be a plurality of additional layers 50, and the plurality of additional layers 50 are provided sequentially in the first direction X. There is no limitation on the number of the additional layers 50.

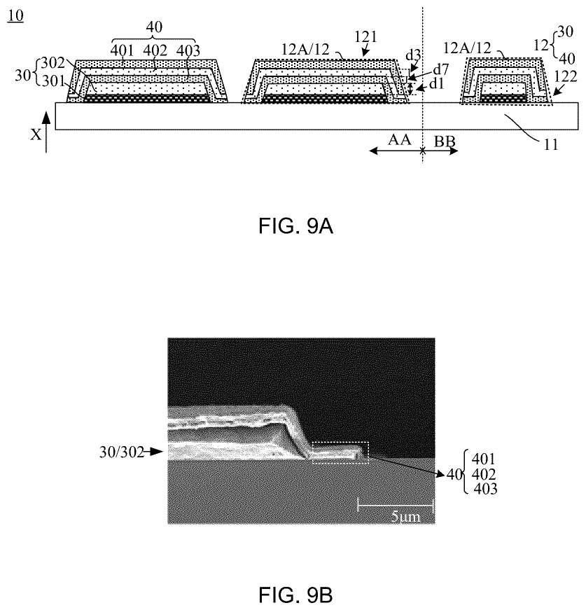

In some embodiments, as shown in FIG. 9A, the second conductive layer 40 further includes a third main material layer 402 and a second stop layer 403. The second stop layer 403, the third main material layer 402 and the second protective layer 401 are sequentially stacked in the first direction X. The first direction X is a direction perpendicular to the base substrate 11 and from the base substrate 11 towards the first conductive layer 30. A material of the third main material layer 402 includes copper, and the third main material layer 402 can form a first intermetallic compound with the solder. The second stop layer 403 can form a fourth intermetallic compound with the solder. A reaction rate between the second stop layer 403 and the solder is less than a reaction rate between the third main material layer 402 and the solder.

For example, as shown in FIG. 9A, a dimension d3 of the third main material layer 402 in the first direction X may be in a range of 1 μm to 10 μm, inclusive. For example, the dimension d3 of the third main material layer 402 in the first direction X is 1 μm, 2 μm, 3 μm, 4 μm, 5 μm, 6 μm, 7 μm, 8 μm, 9 μm or 10 μm, which is not limited here.

For example, as shown in FIG. 9A, a dimension d7 of the second stop layer 403 in the first direction X is in a range of 100 Å to 10000 Å, inclusive. For example, the dimension d7 of the second stop layer 403 in the first direction X is 100 Å, 400 Å, 800 Å, 1000 Å, 6000 Å, 9000 Å or 10000 Å, which is not limited here.

For example, as shown in FIG. 9A, the electrical pattern 12 includes a first main material layer 302, a second stop layer 403, a third main material layer 402, and a second protective layer 401 that are sequentially provided in the first direction X. In a case where the electrical pattern 12 includes the first main material layer 302, adding a third main material layer 402 may increase the thickness of the electrical pattern 12, thereby effectively reducing the risk of the connection pad 12A forming the intermetallic compound completely and reducing the risk of the connection pad 12A falling off.

Since the material of the third main material layer 402 includes copper, the copper in the third main material layer 402 and the tin in the solder may form a first intermetallic compound. The reaction rate between the second stop layer 403 and the solder is less than the reaction rate between the third main material layer 402 and the solder. It can also be understood that the reaction rate between the second stop layer 403 and the solder is less than a reaction rate between the first main material layer 302 and the solder.

In a process of soldering the pins of the electronic component 20 and the connection pads 12A using the solder, the solder and the second protective layer 401 form a second intermetallic compound, and then the solder and the third main material layer 402 form a first intermetallic compound. Since the reaction rate between the second stop layer 403 and the solder is less than the reaction rate between the first main material layer 302 (the third main material layer 402) and the solder, the second stop layer 403 may effectively prevent the solder from further reacting deep into the electrical pattern 12. Therefore, the provision of the second conductive layer 40 further including the third main material layer 402 and the second stop layer 403 may reduce the risk of the connection pad 12A forming the intermetallic compound completely, thereby effectively reducing the risk of the connection pad 12A falling off.

For example, a material of the second stop layer 403 includes any of nickel and nickel alloys.

For example, the nickel alloys include an (n+1) element alloy by doping nickel (Ni) with any n kinds of tungsten (W), vanadium (V), aluminum (Al), copper (Cu), lanthanum (La), lead (Pb), cobalt (Co), silver (Ag), antimony (Sb), indium (In), gallium (Ga), zinc (Zn), tantalum (Ta), ruthenium (Ru), titanium (Ti), bismuth (Bi), neodymium (Nd), chromium (Cr), molybdenum (Mo), yttrium (Y), iron (Fe), manganese (Mn), silicon (Si), gold (Au), niobium (Nb), boron (B), gadolinium (Gd), cerium (Ce), calcium (Ca), magnesium (Mg), hafnium (Hf), zirconium (Zr), palladium (Pd), germanium (Ge) and tin (Sn), wherein n is a positive integer greater than or equal to 1.

For an introduction to the value of n, reference may be made to the above contents, and details are not repeated here.

Since a reaction rate between the second stop layer 403 formed by any of nickel and nickel alloys and the solder is less than the reaction rate between the first main material layer 302 (the third main material layer 402) and the solder, the risk of the connection pad 12A forming the intermetallic compound completely may be reduced, and the risk of the connection pad 12A falling off may be effectively reduced.

The material of the second stop layer 403 includes any of nickel (Ni) and nickel alloys. It can also be understood that a reaction rate between nickel (Ni) and tin (Sn) in the solder is less than a reaction rate between copper (Cu) and tin (Sn) in the solder.

In some examples, as shown in FIGS. 9A and 9B, the second conductive layer 40 includes a second stop layer 403, a third main material layer 402 and a second protective layer 401. The second stop layer 403, the third main material layer 402 and the second protective layer 401 are sequentially stacked in the first direction X. The second conductive layer 40 includes a first covering area 41 and a second covering area 42. It can be seen from FIG. 9B that, the second conductive layer 40 has a good wrapping effect on the first conductive layer 30, thereby improving the oxidation resistance of the electrical pattern 12.

In some embodiments, as shown in FIGS. 5A and 9A, in a case where the electrical pattern 12 includes a second main material layer 501 and a third main material layer 402, a sum of dimensions of the first main material layer 302, the second main material layer 501 and the third main material layer 402 in the first direction X is in a range of 1 μm to 15 μm, inclusive.

It will be noted that in a case where the electrical pattern 12 includes the second main material layer 501 and the third main material layer 402, it does not mean that the electrical pattern 12 includes the second main material layer 501 and the third main material layer 402, but rather that there may be a case where one of the layers is included. For example, as shown in FIG. 5A, the electrical pattern 12 includes a first main material layer 302 and a second main material layer 501. Then here, “the sum of the dimensions of the first main material layer 302, the second main material layer 501 and the third main material layer 402 in the first direction X” and “a sum of dimensions of the first main material layer 302 and the second main material layer 501 in the first direction X” are the same.

That is, a sum of dimensions of all the main material layers (including the first main material layer 302, the second main material layer 501 and the third main material layer 402) in the electrical pattern 12 in the first direction X is in a range of 1 μm to 15 μm, inclusive. For example, the sum of the dimensions of all the main material layers in the electrical pattern 12 in the first direction X is 1 μm, 3 μm, 5 μm, 8 μm, 10 μm, 12 μm or 15 μm, which is not limited here.

For example, as shown in FIG. 5A, the electrical pattern 12 includes a first main material layer 302 and a second main material layer 501. A sum of the dimension d1 of the first main material layer 302 in the first direction X and the dimension d2 of the second main material layer 501 in the first direction X is in a range of 1 μm to 15 μm, inclusive (i.e., 1 μm≤(d1+d2)≤15 μm).

For example, as shown in FIG. 9A, the electrical pattern 12 includes a first main material layer 302 and a third main material layer 402. A sum of the dimension d1 of the first main material layer 302 in the first direction X and the dimension d3 of the third main material layer 402 in the first direction X is in a range of 1 μm to 15 μm, inclusive (i.e., 1 μm≤(d1+d3)≤15 μm).

In some embodiments, as shown in FIGS. 3A to 6 and 9A, the first conductive layer 30 further includes an adhesive layer 301, and the adhesive layer 301 is disposed on a side of the first main material layer 302 proximate to the base substrate 11.

For example, as shown in FIG. 3A, the first conductive layer 30 includes an adhesive layer 301. The electrical pattern 12 includes the adhesive layer 301, the first main material layer 302 and the first protective layer 303 that are provided sequentially in the first direction X.

For example, as shown in FIG. 3D, the first conductive layer 30 includes an adhesive layer 301. The electrical pattern 12 includes the adhesive layer 301, the first main material layer 302 and the second protective layer 401 that are provided sequentially in the first direction X.

For example, as shown in FIG. 4, the first conductive layer 30 includes an adhesive layer 301. The electrical pattern 12 includes the adhesive layer 301, the first main material layer 302, the first protective layer 303 and the second protective layer 401 that are provided sequentially in the first direction X.

For example, as shown in FIG. 5A, the first conductive layer 30 includes an adhesive layer 301. The electrical pattern 12 includes the adhesive layer 301, the second main material layer 501, the first stop layer 502, the first main material layer 302 and the first protective layer 303 that are provided sequentially in the first direction X.

For example, as shown in FIG. 6, the first conductive layer 30 includes an adhesive layer 301. The electrical pattern 12 includes the adhesive layer 301, the second main material layer 501, the first stop layer 502, the first main material layer 302, the first protective layer 303 and the second protective layer 401 that are provided sequentially in the first direction X.

For example, as shown in FIG. 9A, the first conductive layer 30 includes an adhesive layer 301. The electrical pattern 12 includes the adhesive layer 301, the first main material layer 302, the second stop layer 403, the third main material layer 402 and the second protective layer 401 that are provided sequentially in the first direction X.

By providing the adhesive layer 301 on a side of the first main material layer 302 proximate to the base substrate 11, the adhesion between the electrical pattern 12 and the base substrate 11 may be improved.

In some embodiments, a material of the adhesive layer 301 includes any of molybdenum-nickel-titanium (MoNiTi), molybdenum-niobium alloy (MoNb), molybdenum (Mo), titanium (Ti), molybdenum-titanium alloy (MoTi), molybdenum-tungsten alloy (MoW) and molybdenum-tantalum alloy (MoTa).

For example, as shown in FIG. 3A, a dimension d8 of the adhesive layer 301 in the first direction X is in a range of 200 Å to 1000 Å, inclusive. For example, the dimension d8 of the adhesive layer 301 in the first direction X is 200 Å, 300 Å, 500 Å, 600 Å, 700 Å, 800 Å or 1000 Å, which is not limited here.

In a case where the material of the adhesive layer 301 includes any of molybdenum-nickel-titanium alloy (MoNiTi), molybdenum-niobium alloy (MoNb), molybdenum (Mo), titanium (Ti), molybdenum-titanium alloy (MoTi), molybdenum-tungsten alloy (MoW) and molybdenum-tantalum alloy (MoTa), the adhesive layer 301 cannot react with the solder, so as to prevent the solder from diffusing to the base substrate 11.

In some embodiments, the material of the adhesive layer 301 includes any of nickel (Ni) and nickel alloys.

For example, the nickel alloys include an (n+1) element alloy by doping nickel (Ni) with any n kinds of tungsten (W), vanadium (V), aluminum (Al), copper (Cu), lanthanum (La), lead (Pb), cobalt (Co), silver (Ag), antimony (Sb), indium (In), gallium (Ga), zinc (Zn), tantalum (Ta), ruthenium (Ru), titanium (Ti), bismuth (Bi), neodymium (Nd), chromium (Cr), molybdenum (Mo), yttrium (Y), iron (Fe), manganese (Mn), silicon (Si), gold (Au), niobium (Nb), boron (B), gadolinium (Gd), cerium (Ce), calcium (Ca), magnesium (Mg), hafnium (Hf), zirconium (Zr), palladium (Pd), germanium (Ge) and tin (Sn), wherein n is a positive integer greater than or equal to 1.

For an introduction to the value of n, reference may be made to the above contents, and details are not repeated here.

By providing the material of the adhesive layer 301 to be any of nickel (Ni) and nickel alloys, the adhesion between the electrical pattern 12 and the base substrate 11 may be improved.

For example, as shown in FIG. 3A, a dimension d8 of the adhesive layer 301 in the first direction X is in a range of 100 Å to 10000 Å, inclusive. For example, the dimension d8 of the adhesive layer 301 in the first direction X is 100 Å, 400 Å, 900 Å, 1000 Å, 2000 Å, 7000 Å or 10000 Å, which is not limited here.

It can be known from the introduction about the material of each film layer in the above contents that, the material of the first protective layer 303, the material of the second protective layer 401, the material of the first stop layer 502, the material of the second stop layer 403 and the material of the adhesive layer 301 may each be any of nickel (Ni) and nickel alloys. Multiple film layers may be formed using the same materials, so that a coating chamber may be shared during forming the film layers, which is beneficial to simplifying the manufacturing process of the circuit board 10.

In some embodiments, as shown in FIGS. 5A and 9A, a sum of dimensions of the first stop layer 502, the second stop layer 403, the adhesive layer 301, the first protective layer 303 and the second protective layer 401 in the first direction X is in a range of 0.02 μm to 2 μm, inclusive.

It will be noted that the sum of the dimensions of the first stop layer 502, the second stop layer 403, the adhesive layer 301, the first protective layer 303 and the second protective layer 401 in the first direction X does not mean that the embodiments include all the film layers of the first stop layer 502, the second stop layer 403, the adhesive layer 301, the first protective layer 303 and the second protective layer 401, but means that if a film layer exists in the embodiments, a thickness of the film layer is calculated, and if a film layer does not exist in the embodiments, a thickness of the film layer is not calculated.

For example, the sum of the dimensions of the first stop layer 502, the second stop layer 403, the adhesive layer 301, the first protective layer 303 and the second protective layer 401 in the first direction X is 0.02 μm, 0.08 μm, 0.1 μm, 0.3 μm, 1 μm, 1.5 μm, 1.8 μm or 2 μm, which is not limited here.

In some embodiments, in the nickel alloys, a percentage of nickel atomics in the nickel-copper alloy (NiCu) is greater than or equal to 10%, and a percentage of nickel atomics in the remaining nickel alloys is greater than or equal to 40%.

For example, a percentage of nickel atomics in the nickel-copper alloy (NiCu) is 10%, 20%, 30%, 50%, 60% or 80%, which is not limited here.

Both copper (Cu) and nickel (Ni) may react with tin (Sn) in the solder to form intermetallic compounds. Therefore, the percentage of the nickel atomics in the nickel-copper alloy (NiCu) is provided to be greater than or equal to 10%, so that in a case where any of the first protective layer 303 or the second protective layer 401 uses the nickel-copper alloy, the nickel-copper alloy not only has the oxidation resistance, but also may be directly connected to the pins of the electronic component 20 by the solder.

In a case where any of the first stop layer 502 and the second stop layer 403 uses the nickel-copper alloy, the presence of nickel (Ni) may effectively ensure that the reaction rate between the first stop layer 502 (the second stop layer 403) and the solder is less than the reaction rate between the first main material layer 302 (the second main material layer 501) and the solder. In this way, the solder may be effectively prevented from further reacting deep into the electrical pattern 12, thereby effectively reducing the risk of the connection pad 12A falling off.

For example, in a nickel alloy other than nickel-copper alloys (NiCu) of the nickel alloys, a percentage of nickel atomics is 40%, 45%, 50%, 60%, 70%, 80%, 90% or 99%, which is not limited here.

By setting the percentage of nickel atomics in the nickel alloy other than nickel-copper alloy (NiCu) of the nickel alloys to be greater than or equal to 40%, in a case where any of the first protective layer 303 and the second protective layer 401 uses the nickel alloy, the nickel alloy has good oxidation resistance.

In a case where any of the first stop layer 502 and the second stop layer 403 uses the nickel alloy, the solder may be effectively prevented from further reacting deep into the electrical pattern 12, the risk of the connection pad 12A forming the intermetallic compound completely may be reduced, and the risk of the connection pad 12A falling off may be effectively reduced.

For example, in order to verify that the nickel alloy has good oxidation resistance, the following experimental data are provided.

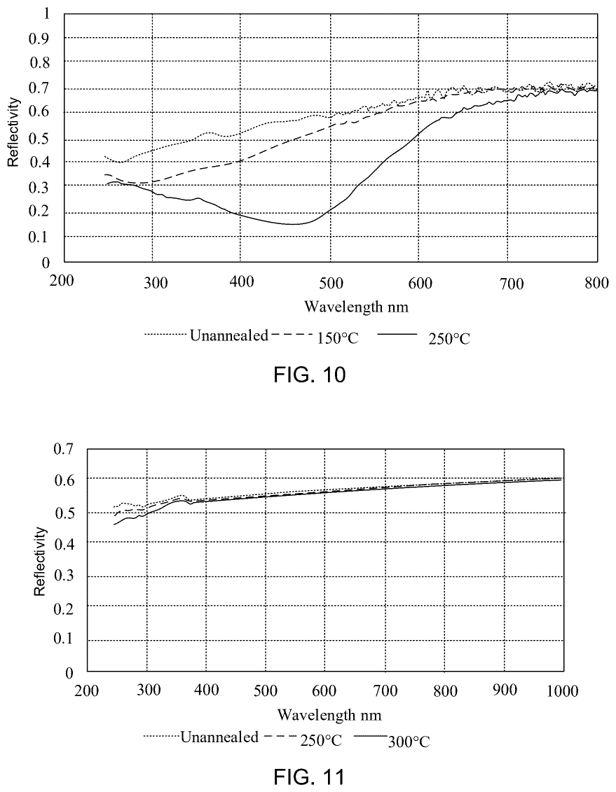

FIG. 10 is a curve graph of reflectivity of the copper-nickel alloy (CuNi). FIG. 11 is a curve graph of reflectivity of the nickel-tungsten alloy (NiW). The copper-nickel alloy (CuNi) and the nickel-tungsten alloy (NiW) contain the same percentage of nickel atomics.

It will be noted that in the related art, a surface treatment method of forming a copper alloy layer may be used to treat the electrical pattern (or the connection pads) to increase the oxidation resistance of the electrical pattern (or the connection pads). In the embodiments of the present disclosure, the protective layers (the first protective layer 303 and the second protective layer 401) containing nickel alloys are used to enhance the oxidation resistance of the electrical pattern 12. The oxidation of the electrical pattern 12 mainly occurs on its surface. Therefore, slight changes on the material surface may be characterized by a surface reflectivity of the material. After the material is annealed under different temperature conditions, the smaller the reflectivity changes, the stronger the oxidation resistance of the material. The decrease in reflectivity indicates poor oxidation resistance of the material.

As shown in FIGS. 10 and 11, a vertical coordinate represents reflectivity, and a horizontal coordinate represents wavelength. After annealing at 150° C. and 250° C., the reflectivity of the copper-nickel alloy (CuNi) decreases significantly. The higher the annealing temperature, the more obvious the decrease in reflectivity. The reflectivity of the nickel-tungsten alloy (NiW) does not change much before and after annealing, which shows that the nickel-tungsten alloy (NiW) has relatively good oxidation resistance.

The embodiments of the present disclosure also tested the corrosion resistance of nickel-tungsten alloy (NiW), electroless nickel/immersion gold and copper-nickel alloy (CuNi).

The above three materials are placed for 200 hours at 85° C. and 85% humidity. It can be seed from the results that the corrosion resistance of the nickel-tungsten alloy (NiW) is significantly better than that of the electroless nickel/immersion gold and that of the copper-nickel alloy (CuNi).

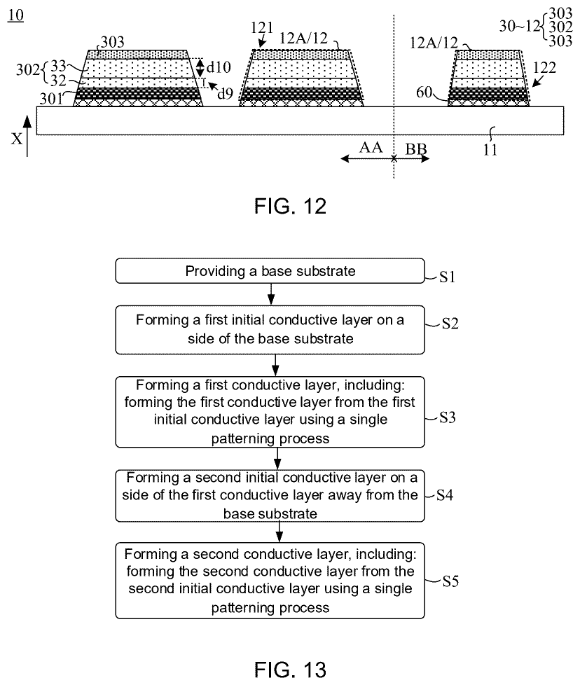

In some embodiments, as shown in FIG. 12, the first main material layer 302 includes a seed layer 32 and a growth layer 33 that are stacked in the first direction X. The first direction X is a direction perpendicular to the base substrate 11 and from the base substrate 11 towards the first conductive layer 30. A dimension d9 of the seed layer 32 in the first direction X is in a range of 1000 Å to 9000 Å, inclusive. A dimension d10 of the growth layer 33 in the first direction X is in a range of 2 μm to 15 μm, inclusive.

For example, the dimension d9 of the seed layer 32 in the first direction X is 1000 Å, 3000 Å, 5000 Å, 7000 Å, 8000 Å or 9000 Å, which is not limited here.

For example, the dimension d10 of the growth layer 33 in the first direction X is 2 μm, 4 μm, 6 μm, 8 μm, 10 μm, 11 μm, 12 μm, 13 μm, 14 μm or 15 μm, which is not limited here.

For example, by providing the first main material layer 302 including the seed layer 32 and the growth layer 33, the first main material layer 302 may be formed by an electroplating process. That is, the first main material layer 302 in the electrical pattern 12 provided in the embodiments of the present disclosure may be formed by a sputtering process or by an electroplating process.

For example, an electroplating process for forming the first main material layer 302 may be an additive electroplating process or a subtractive electroplating process. The additive electroplating process is to apply a photoresist by coating, then form the first main material layer 302, and then remove the photoresist. The subtractive electroplating process is to form a whole initial material layer, and then perform a photolithography process to form the first main material layer 302.

In some embodiments, as shown in FIG. 12, a reverse stress layer 60 is provided between the base substrate 11 and the first conductive layer 30, and a material of the reverse stress layer 60 includes any of silicon nitride and silicon oxide.

The reverse stress layer 60 and the main material layers including copper (e.g., the first main material layer 302, the second main material layer 501 and the third main material layer 402) generate opposite stress. For example, the main material layer is made of a material that generates tensile stress, and the reverse stress layer 60 is made of a material that generates compressive stress. The provision of the reverse stress layer 60 may reduce warping of the electrical pattern 12. It will be noted that warping refers to a situation where a material is not formed according to the designed shape, so that the material forms a distorted shape.

It can be understood that the circuit board 10 provided in any of the above embodiments may be provided with a reverse stress layer 60 to reduce the warping of the electrical pattern 12.

In some embodiments, as shown in FIGS. 3A, 3D, 4, 5A, 6, 9A and 12, the circuit board 10 has a plurality of edges. The circuit board 10 includes a device area AA and at least one bonding area BB, and the bonding area BB is closer to any edge of the circuit board 10 than the device area AA. The electronic component 20 includes a light-emitting device and a microchip. The plurality of connection pads 12A are divided into a plurality of device connection pads 121 and a plurality of chip connection pads 122. The device connection pad 121 is configured to be connected to a light-emitting device, and the chip connection pad 122 is configured to be connected to a microchip. The plurality of device connection pads 121 are located in the device area AA, and the plurality of chip connection pads 122 are located in the bonding area BB.

It will be noted that the plurality of device connection pads 121 are located in the device area AA, and the plurality of chip connection pads 122 are located in the bonding area BB, which is only an example but not a limitation on the structure.

It can be understood that an edge of the bonding area BB proximate to the device area AA is adjacent to an edge of the device area AA proximate to the bonding area BB. The bonding area BB is closer to any edge of the circuit board 10 relative to the device area AA, that is, the bonding area BB may be located between the device area AA and any edge.

That is, whether in the device area AA or in the bonding area BB of the circuit board 10, the connection pad 12A and the electrical pattern 12 are located in the same conductive layer, which facilitates the manufacture of the circuit board 10 and may save costs.

In another aspect, some embodiments of the present disclosure provide a method for manufacturing a circuit board 10. As shown in FIG. 13, the method includes steps S1 to S3. Alternatively, the method includes steps S1 to S5.

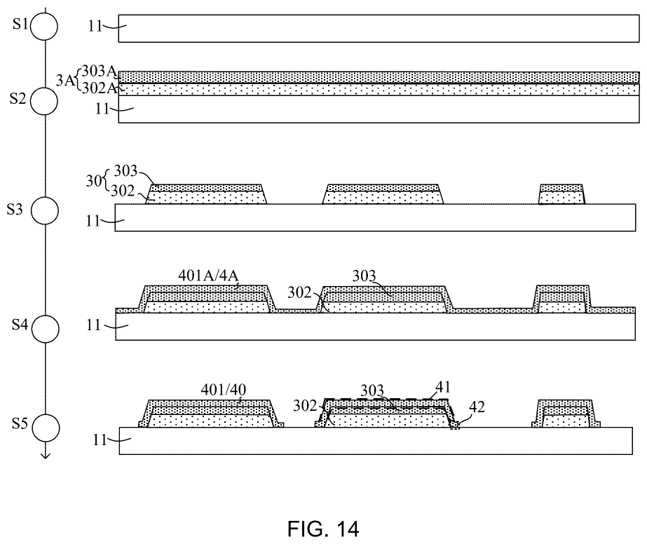

It can be understood that, for example, as shown in FIG. 3A, in a case where the circuit board 10 does not include the second conductive layer 40, the method includes the steps S1 to S3. For example, as shown in FIG. 3D, in a case where the circuit board 10 includes the second conductive layer 40, the method includes the steps S1 to S5. In S1, as shown in FIG. 14, a base substrate 11 is provided.

For example, the base substrate 11 includes a glass substrate, and the glass substrate includes alkali-free glass, alkali glass, reinforced glass or tempered glass.

In S2, as shown in FIG. 14, a first initial conductive layer 3A is formed on a side of the base substrate 11.

For example, the first initial conductive layer 3A includes a first initial main material layer 302A and a first initial protective layer 303A.

For example, the first initial main material layer 302A is formed on a side of the base substrate 11 by sputtering, and the first initial protective layer 303A is formed on a side of the first initial main material layer 302A away from the base substrate 11 by sputtering.

In S3, as shown in FIG. 14, a first conductive layer 30 is formed, which includes: forming the first conductive layer 30 from the first initial conductive layer 3A using a single patterning process.

For example, the first initial main material layer 302A forms the first main material layer 302, and the first initial protective layer 303A forms the first protective layer 303.

It will be noted that “the patterning process” generally includes photoresist coating, exposure, development, etching, photoresist stripping and other steps. The expression “a single patterning process” means a process of forming a patterned layer, component or member using a mask. Here, a single patterning process means forming a patterned layer using a mask.

In S4, as shown in FIG. 14, a second initial conductive layer 4A is formed on a side of the first conductive layer 30 away from the base substrate 11.

For example, the second initial conductive layer 4A includes a second initial protective layer 401A.

For example, the second initial protective layer 401A is formed on a side of the first conductive layer 30 away from the base substrate 11 by sputtering.

In S5, as shown in FIG. 14, a second conductive layer 40 is formed, which includes: forming the second conductive layer 40 from the second initial conductive layer 4A using a single patterning process.

For example, the second initial protective layer 401A forms the second protective layer 401. The second protective layer 401 includes a first covering area 41 and a second covering area 42. For the introduction of the first covering area 41 and the second covering area 42, reference may be made to the above contents and details are not repeated here.

In the embodiments provided by the present disclosure, in a case where the method for manufacturing the circuit board includes the steps S1 to S3, the electrical pattern 12 is formed through a single patterning process. The method for manufacturing the circuit board is simple, the number of the masks is reduced, and the cost of the circuit board 10 is reduced. In a case where the method for manufacturing the circuit board includes the steps S1 to S5, the electrical pattern 12 is formed by two patterning processes, that is, the electrical pattern 12 in which the second conductive layer 40 wraps the first conductive layer 30 is formed using two masks, thereby improving the oxidation resistance of the edge of the electrical pattern 12.

The method for manufacturing the circuit board will be introduced exemplarily below.

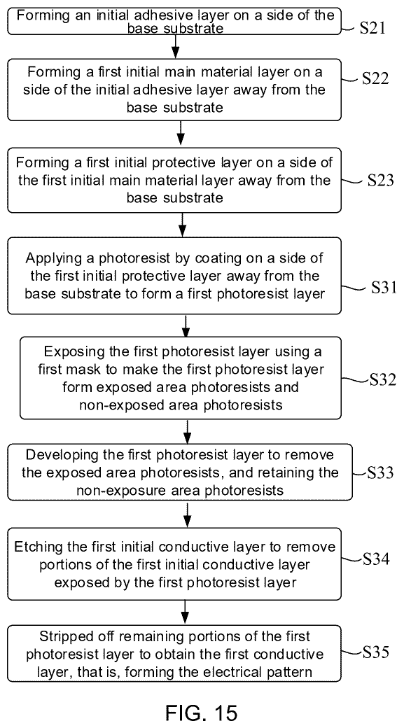

In some embodiments, taking an example of forming the circuit board 10 shown in FIG. 3A, as shown in FIG. 15, forming the first initial conductive layer 3A on a side of the base substrate 11 in step S2 includes S21 to S23; and forming the first conductive layer 30 in step S3 includes S31 to S35.

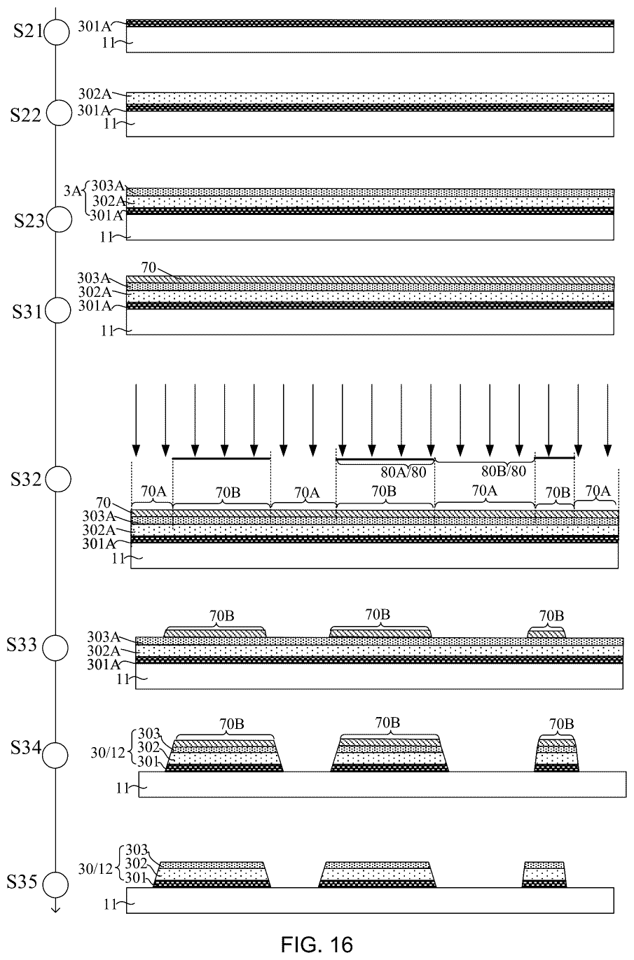

In S21, as shown in FIG. 16, an initial adhesive layer 301A is formed on a side of the base substrate 11.

For example, the initial adhesive layer 301A is formed by sputtering.

In S22, as shown in FIG. 16, the first initial main material layer 302A is formed on a side of the initial adhesive layer 301A away from the base substrate 11.

For example, the first initial main material layer 302A is formed by sputtering.

In some other examples, the first initial main material layer 302A is formed by an electroplating process, which is not limited here.

In S23, as shown in FIG. 16, the first initial protective layer 303A is formed on a side of the first initial main material layer 302A away from the base substrate 11. For example, the first initial protective layer 303A is formed by sputtering.

For example, as shown in FIG. 16, the initial adhesive layer 301A, the first initial main material layer 302A and the first initial protective layer 303A that are stacked constitute the first initial conductive layer 3A.

In S31, as shown in FIG. 16, a photoresist is applied by coating on a side of the first initial protective layer 303A away from the base substrate 11 to form a first photoresist layer 70.

For example, a material of the first photoresist layer 70 is polyimide. A photoresist material is applied by coating on the first initial protective layer 303A to form the first photoresist layer 70.

In S32, as shown in FIG. 16, the first photoresist layer 70 is exposed using a first mask 80 to make the first photoresist layer 70 form exposed area photoresists 70A and non-exposed area photoresists 70B.

For example, the first mask 80 includes a plurality of shading areas 80A and a plurality of opening areas 80B. The shading areas 80A block light and correspond to the non-exposed area photoresists 70B in the first photoresist layer 70. The opening areas 80B do not block light and correspond to the exposed area photoresists 70A in the first photoresist layer 70. After exposure, the first photoresist layer 70 forms non-exposed area photoresists 70B and exposed area photoresists 70A corresponding to the shading areas 80A and the opening areas 80B of the first mask 80.

It will be noted that “A corresponding to B” above means that in the first direction X, orthographic projections of A and B on the base substrate 11 coincide with each other.

In S33, as shown in FIG. 16, the first photoresist layer 70 is developed to remove the exposed area photoresists 70A, and the non-exposure area photoresists 70B are retained.

For example, the first photoresist layer 70 is developed using a developer.

In S34, as shown in FIG. 16, the first initial conductive layer 3A is etched to remove portions of the first initial conductive layer 3A exposed by the first photoresist layer 70.

For example, the first initial conductive layer 3A is etched by dry etching. Portions of the first initial conductive layer 3A blocked by the first photoresist layer 70 are retained, and portions of the first initial conductive layer 3A exposed by the first photoresist layer 70 are removed.

The initial adhesive layer 301A forms the adhesive layer 301, the first initial main material layer 302A forms the first main material layer 302, and the first initial protective layer 303A forms the first protective layer 303.

In S35, as shown in FIG. 16, the remaining portions of the first photoresist layer 70 are stripped off to obtain the first conductive layer 30, that is, the electrical pattern 12 is formed.

The remaining portions of the first photoresist layer 70 are non-exposed area photoresists 70B.

Therefore, in the present embodiments, the electrical pattern 12 is formed by a single patterning process through steps S21 to S23 and S31 to S35.

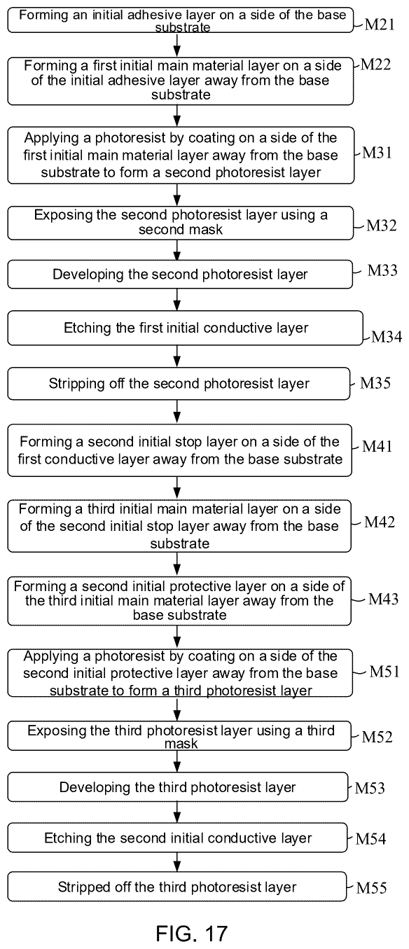

In some embodiments, taking an example of forming the circuit board 10 shown in FIG. 9A, as shown in FIG. 17, forming the first initial conductive layer 3A on a side of the base substrate 11 in step S2 includes M21 to M22; forming the first conductive layer 30 in step S3 includes M31 to M35; forming the second initial conductive layer 4A in step S4 includes M41 to M43; and forming the second conductive layer 40 in step S5 includes M51 to M55.

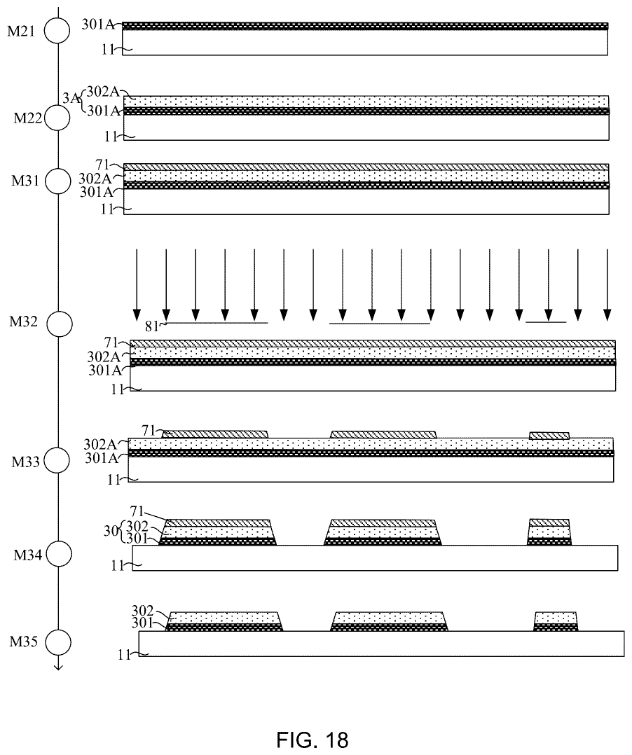

In M21, as shown in FIG. 18, an initial adhesive layer 301A is formed on a side of the base substrate 11.

In M22, as shown in FIG. 18, the first initial main material layer 302A is formed on a side of the initial adhesive layer 301A away from the base substrate 11.

Forming the first initial conductive layer 3A includes forming the initial adhesive layer 301A and the first initial main material layer 302A.

In M31, as shown in FIG. 18, a photoresist is applied by coating on a side of the first initial main material layer 302A away from the base substrate 11 to form a second photoresist layer 71.

In M32, as shown in FIG. 18, the second photoresist layer 71 is exposed using a second mask 81.

In M33, as shown in FIG. 18, the second photoresist layer 71 is developed.

In M34, as shown in FIG. 18, the first initial conductive layer 3A is etched.

The initial adhesive layer 301A forms the adhesive layer 301, and the first initial main material layer 302A forms the first main material layer 302, thereby forming the first conductive layer 30.

In M35, as shown in FIG. 18, the second photoresist layer 71 is stripped off.

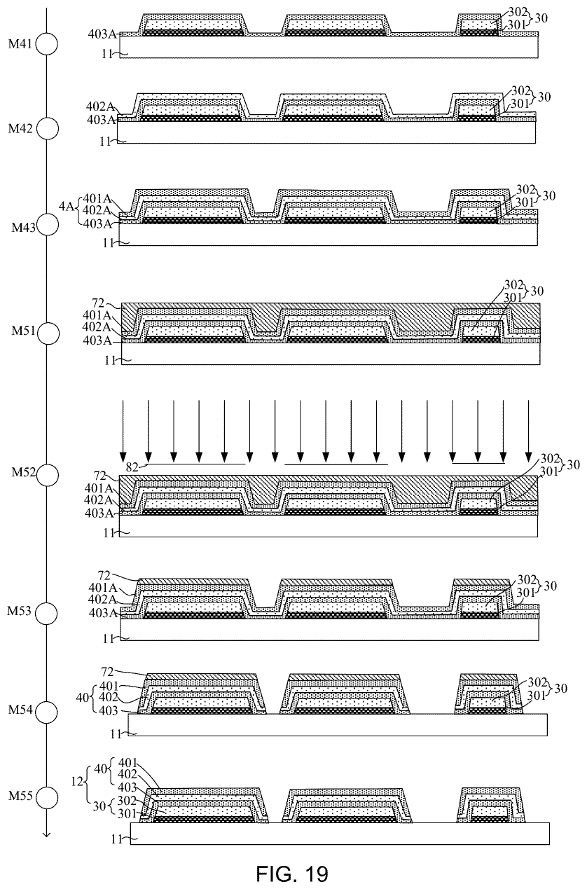

In M41, as shown in FIG. 19, a second initial stop layer 403A is formed on a side of the first conductive layer 30 away from the base substrate 11.

In M42, as shown in FIG. 19, a third initial main material layer 402A is formed on a side of the second initial stop layer 403A away from the base substrate 11.

In M43, as shown in FIG. 19, a second initial protective layer 401A is formed on a side of the third initial main material layer 402A away from the base substrate 11.

The second initial conductive layer 4A is formed, and the second initial conductive layer 4A includes the second initial stop layer 403A, the third initial main material layer 402A and the second initial protective layer 401A.

In M51, as shown in FIG. 19, a photoresist is applied by coating on a side of the second initial protective layer 401A away from the base substrate 11 to form a third photoresist layer 72.

In M52, as shown in FIG. 19, the third photoresist layer 72 is exposed using a third mask 82.

In M53, as shown in FIG. 19, the third photoresist layer 72 is developed.

In M54, as shown in FIG. 19, the second initial conductive layer 4A is etched.

The second initial stop layer 403A forms a second stop layer 403, the third initial main material layer 402A forms a third main material layer 402, and the second initial protective layer 401A forms a second protective layer 401, thereby forming the second conductive layer 40.

In M55, as shown in FIG. 19, the third photoresist layer 72 is stripped off.

The second conductive layer 40 and the first conductive layer 30 form the electrical pattern 12.

Therefore, in the present embodiments, the electrical pattern 12 with good oxidation resistance is formed by two patterning processes through steps M21 to M22, M31 to M35, M41 to M43, and M51 to M55.

In yet another aspect, as shown in FIG. 20, some embodiments of the present disclosure further provide a light-emitting substrate 100, and the light-emitting substrate 100 includes the circuit board 10 as described in any of the above embodiments.

The light-emitting substrate 100 further includes an electronic component 20, and the pins of the electronic component 20 are electrically connected to the connection pads 12A of the circuit board 10 by the solder.

For example, the electronic component 20 includes a micro light-emitting diode, a microchip, a micro sensor, or a micro driver, which is not limited here.

For example, as shown in FIG. 20, the light-emitting substrate 100 further includes a reflective layer 91, and the reflective layer 91 is disposed on a side of the electrical pattern 12 away from the base substrate 11. The reflective layer 91 is disposed in the device area AA. The reflective layer 91 is provided with a plurality of openings therein, and the pins of the electronic component 20 are electrically connected to the solder and the connection pads 12A through openings. That is, the pins of the electronic component 20 are connected to device connection pads 121 by the solder.

For example, a material of the reflective layer 91 may include white ink and/or silicone-based white glue. For example, the material of the reflective layer 91 may include resin (e.g., epoxy resin or polytetrafluoroethylene resin), titanium dioxide and an organic solvent (e.g., dipropylene glycol methyl ether).

For example, as shown in FIG. 20, the electronic component 20 includes a light-emitting device, and a light converging layer 92 is provided on a side of the light-emitting device away from the base substrate 11. For example, a material of the light converging layer 92 is an acrylic ester or epoxy material, and the light converging layer 92 has a light converging function.

For example, as shown in FIG. 20, the light-emitting substrate 100 further includes a flexible printed circuit board 94, and the flexible printed circuit board 94 is connected to the chip connection pads 122. A protective adhesive layer 93 is provided on a side of the electrical pattern 12 located in the bonding area BB away from the base substrate 11, and is used for encapsulating the electrical pattern 12 and a portion of the electrical pattern 12 connected to the flexible printed circuit board 94.

In yet another aspect, as shown in FIG. 21, embodiments of the present disclosure further provide a backlight module 200, and the backlight module 200 includes the light-emitting substrate 100 as described in any of the above embodiments. The light-emitting substrate 100 has a light-exit side E and a non-light-exit side F that are opposite. The backlight module 200 further includes a plurality of optical films 220, and the plurality of optical films 220 are disposed on the light-exit side E of the light-emitting substrate 100.

For example, as shown in FIG. 21, the light-exit side E of the light-emitting substrate 100 is a side of the light-emitting substrate 100 providing a light source, and the non-light-exit side F of the light-emitting substrate 100 is the other side opposite to the light-exit side E.

For example, the light-emitting substrate 100 may directly emit white light, and the white light exits after a light uniformizing treatment performed by the plurality of optical films 220. Alternatively, the light-emitting substrate 100 may emit light of another color (e.g., blue light), and then the light exits after color conversion and a light uniformizing treatment performed by the plurality of optical films 220.

For example, as shown in FIG. 21, the plurality of optical films 220 include a diffusion plate 221, a quantum dot film 222, a diffusion sheet 223 and a composite film 224 that are disposed in sequence in a direction from the light-emitting substrate 100 towards the optical films 220.

The diffusion plate 221 can blur the light exit from the light-emitting substrate 100, and provide support for the quantum dot film 222, the diffusion sheet 223 and the composite film 224. Under excitation of light of a single color exit from the light-emitting substrate 100, the quantum dot film 222 may convert the light into lights of three primary colors (e.g., red light, green light and blue light), so as to improve a utilization rate of light energy of the light-emitting substrate 100. The diffusion sheet 223 can perform uniformizing treatment on the light passing through the diffusion sheet 223. The composite film 224 can improve the light extraction efficiency of the backlight module 200.

It will be noted that the composite film 224 may include a brightness enhancement film (BEF) and a dual brightness enhancement film (DBEF). The flux of light within a certain angle range may be enhanced using principles of total reflection, refraction and polarization, so as to increase the brightness of the exiting light.

For example, the light-emitting substrate 100 emits blue light in a direction away from the light-emitting substrate 100. The quantum dot film 222 may include a red quantum dot material, a green quantum dot material, and a transparent material. When the blue light emitted by the light-emitting substrate 100 passes through the red quantum dot material, it is converted into red light; when the blue light passes through the green quantum dot material, it is converted into green light; and the blue light may directly pass through the transparent material. Then, the blue light, the red light and the green light are mixed and superimposed in a certain proportion to present white light. The diffusion plate 221 and the diffusion sheet 223 can mix white light evenly to improve the light shadow generated by the light-emitting substrate 100.

Moreover, beneficial effects of the backlight module 200 are the same as the beneficial effects of the light-emitting substrate 100 provided in the embodiments of the present disclosure, and details are not repeated here.

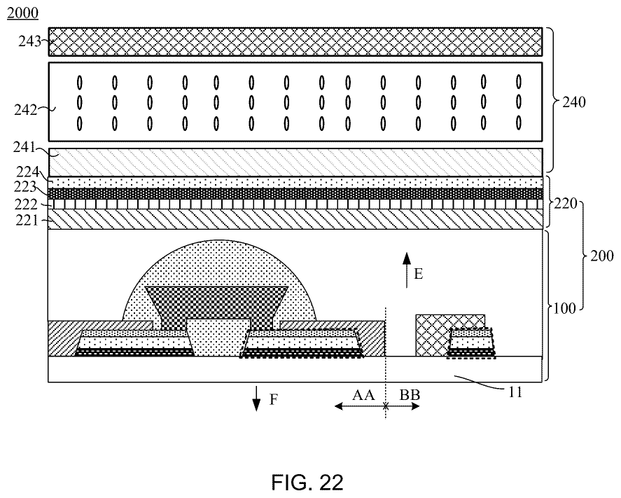

In yet another aspect, as shown in FIG. 22, embodiments of the present disclosure provide a display apparatus 2000 which includes the backlight module 200 as described in any of the above embodiments. The display apparatus 2000 further includes a liquid crystal display panel 240 connected to the backlight module 200.

For example, the liquid crystal display panel 240 includes an array substrate 241, an opposite substrate 243, and a liquid crystal layer 242 disposed between the array substrate 241 and the opposite substrate 243. It can be understood that the light emitted by the light-emitting substrate 100 can pass through the array substrate 241 and be incident on the liquid crystal layer 242. The liquid crystal layer 242 includes liquid crystal molecules. By controlling deflection angles of the liquid crystal molecules, the intensity of light passing through the liquid crystal layer 242 and incident on the opposite substrate 243 can be controlled, so that the display apparatus 2000 can realize the image display function.

In some examples, the display apparatus 2000 may be a product having an image display function. For example, the display apparatus 2000 may be used to display still images such as pictures or photos, and the display apparatus 2000 may also be used to display dynamic images such as videos or game screens.

In some examples, the display apparatus 2000 may be a notebook computer, a mobile phone, a wireless device, a personal digital assistant (PDA), a hand-held or portable computer, a global positioning system (GPS) receiver/navigator, a camera, an MPEG-4 Part 14 (MP4) video player, a video camera, a game console, a watch, a clock, a calculator, a television (TV) monitor, a flat-panel display, a computer monitor, a car display (e.g., an odometer display), a navigator, a cockpit controller and/or display, a camera view display (e.g., a rear view camera display in a vehicle), an electronic photo, an electronic billboard or sign, a projector, a packaging and aesthetic structure (e.g., a display for displaying an image of a piece of jewelry), or the like.

Beneficial effects of the above display apparatus 2000 are the same as the beneficial effects of the light-emitting substrate 100 provided in the embodiments of the present disclosure, and details are not repeated here.

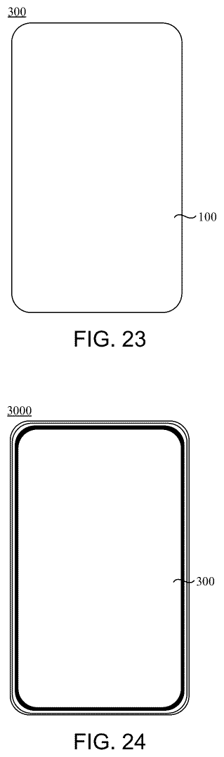

In yet another aspect, as shown in FIG. 23, some embodiments of the present disclosure further provide a display panel 300. The display panel 300 includes the light-emitting substrate 100 as described above.

For example, applying the above light-emitting substrate 100 to a mini-LED display screen may further reduce a dot pitch of the display screen, thereby greatly improve a visual effect of a corresponding terminal product and significantly reducing a viewing distance.

Beneficial effects of the above display panel 300 are the same as the beneficial effects of the light-emitting substrate 100 provided in the embodiments of the present disclosure, and details are not repeated here.

In yet another aspect, as shown in FIG. 24, some embodiments of the present disclosure further provide a display apparatus 3000. The display apparatus 3000 includes the display panel 300 as described above.

In some examples, the display apparatus 3000 further includes a frame, a circuit board, a display driver integrated circuit (IC) and other electronic components. The display panel 300 is provided in the frame.

The display apparatus 3000 may be any apparatus that displays images whether in motion (e.g., a video) or stationary (e.g., a static image), and regardless of text or image. More specifically, it is expected that the described embodiments may be implemented in or associated with a variety of electronic devices. The variety of electronic devices may include (but are not limit to), for example, mobile phones, wireless devices, personal digital assistants (PDAs), hand-held or portable computers, global positioning system (GPS) receivers/navigators, cameras, MPEG-4 Part 14 (MP4) video players, video cameras, game consoles, watches, clocks, calculators, TV monitors, flat-panel displays, computer monitors, car displays (e.g., odometer displays), navigators, cockpit controllers and/or displays, camera view displays (e.g., display of rear view camera in vehicles), electronic photos, electronic billboards or signs, projectors, architectural structures, packaging and aesthetic structures (e.g., displays for displaying an image of a piece of jewelry), etc.

Beneficial effects of the display apparatus 3000 are the same as the beneficial effects of the light-emitting substrate 100 provided in the embodiments of the present disclosure, and details are not repeated here.

The foregoing descriptions are merely specific implementations of the present disclosure, but the protection scope of the present disclosure is not limited thereto. Changes or replacements that any person skilled in the art could conceive of within the technical scope of the present disclosure shall be included in the protection scope of the present disclosure. Therefore, the protection scope of the present disclosure shall be subject to the protection scope of the claims.

1. A circuit board, comprising:
a base substrate; and
an electrical pattern disposed on the base substrate; the electrical pattern including a plurality of conductive patterns and a plurality of connection pads, a conductive pattern being electrically connected to at least one connection pad, and the connection pad being used to be connected to an electronic component, wherein
the electrical pattern is composed of at least one of a first conductive layer and and/or a second conductive layer; the second conductive layer covers a surface of the first conductive layer away from the base substrate and two sides of the first conductive layer along an extension direction of the first conductive layer;
the first conductive layer includes a first main material layer, a material of the first main material layer includes copper, and the first main material layer is capable of forming a first intermetallic compound with solder;
the electrical pattern includes: at least one of a first protective layer and a second protective layer; the first protective layer is included in the first conductive layer, and the first protective layer is disposed on a side of the first main material layer away from the base substrate; the second protective layer is included in the second conductive layer; the first protective layer and the second protective layer are used to enhance oxidation resistance of the electrical pattern; and
any of the first protective layer and the second protective layer is capable of forming a second intermetallic compound with the solder.

2. The circuit board according to claim 1, wherein the first conductive layer further includes: at least one additional layer disposed between the first main material layer and the base substrate, wherein the additional layer includes a second main material layer and a first stop layer that are stacked in a first direction; the first direction is a direction perpendicular to the base substrate and from the base substrate towards the first conductive layer;
a material of the second main material layer includes copper, and the second main material layer is capable of forming a first intermetallic compound with the solder; and
the first stop layer is capable of forming a third intermetallic compound with the solder, and a reaction rate between the first stop layer and the solder is less than a reaction rate between the second main material layer and the solder.

3. The circuit board according to claim 1, wherein the second conductive layer further includes: a third main material layer and a second stop layer; the second stop layer, the third main material layer and the second protective layer are sequentially stacked in a first direction; the first direction is a direction perpendicular to the base substrate and from the base substrate towards the first conductive layer;
a material of the third main material layer includes copper, and the third main material layer is capable of forming a first intermetallic compound with the solder; and
the second stop layer is capable of forming a fourth intermetallic compound with the solder, and a reaction rate between the second stop layer and the solder is less than a reaction rate between the third main material layer and the solder.

4. The circuit board according to claim 1, wherein the second conductive layer includes a first covering area and a second covering area that are connected; an orthographic projection of the first covering area on the base substrate covers an orthographic projection of the first conductive layer on the base substrate, and an orthographic projection of the second covering area on the base substrate is located on a side of the orthographic projection of the first conductive layer on the base substrate along the extension direction of the first conductive layer; and a distance between a side surface of the second covering area away from the first conductive layer and the first conductive layer is greater than or equal to 2 μm.

5. The circuit board according to claim 1, wherein the first conductive layer further includes an adhesive layer, and the adhesive layer is disposed on a side of the first main material layer proximate to the base substrate; or
the first conductive layer further includes an adhesive layer, and the adhesive layer is disposed on a side of the first main material layer proximate to the base substrate; and a material of the adhesive layer includes any of molybdenum-nickel-titanium, molybdenum-niobium alloy, molybdenum, titanium, molybdenum-titanium alloy, molybdenum-tungsten alloy and molybdenum-tantalum alloy.

6. (canceled)

7. The circuit board according to claim 1, wherein the first conductive layer further includes a first stop layer and an adhesive layer, and the second conductive layer further includes a second stop layer; a material of the first protective layer, a material of the second protective layer, a material of the first stop layer, a material of the second stop layer and a material of the adhesive layer each include any of nickel and nickel alloys.

8. The circuit board according to claim 7, wherein the nickel alloys include an (n+1) element alloy by doping nickel with any n kinds of tungsten, vanadium, aluminum, copper, lanthanum, lead, cobalt, silver, antimony, indium, gallium, zinc, tantalum, ruthenium, titanium, bismuth, neodymium, chromium, molybdenum, yttrium, iron, manganese, silicon, gold, niobium, boron, gadolinium, cerium, calcium, magnesium, hafnium, zirconium, palladium, germanium and tin, wherein n is a positive integer greater than or equal to 1.

9. The circuit board according to claim 8, wherein in the nickel alloys,
a percentage of nickel atomics in a nickel-copper alloy is greater than or equal to 10%; and
a percentage of nickel atomics in remaining nickel alloys is greater than or equal to 40%.

10. The circuit board according to claim 1, wherein
the first conductive layer further includes a second main material layer, and the second conductive layer further includes a third main material layer; a sum of dimensions of the first main material layer, the second main material layer and the third main material layer in a first direction is in a range of 1 μm to 15 μm, inclusive; and a dimension of any of the first main material layer, the second main material layer and the third main material layer in the first direction is in a range of 1 μm to 10 μm, inclusive; wherein
the first direction is a direction perpendicular to the base substrate and from the base substrate towards the first conductive layer.

11. The circuit board according to claim 1, wherein the first main material layer includes: a seed layer and a growth layer that are stacked in a first direction; the first direction is a direction perpendicular to the base substrate and from the base substrate towards the first conductive layer;
a dimension of the seed layer in the first direction is in a range of 1000 Å to 9000 Å, inclusive; and
a dimension of the growth layer in the first direction is in a range of 2 μm to 15 μm, inclusive.

12. The circuit board according to claim 1, further comprising a reverse stress layer located between the base substrate and the first conductive layer, wherein a material of the reverse stress layer includes any of silicon nitride and silicon oxide.

13. The circuit board according to claim 1, wherein the circuit board has a plurality of edges; the circuit board has a device area and at least one bonding area, and the bonding area is closer to any edge of the circuit board than the device area; and
the plurality of connection pads are divided into a plurality of device connection pads and a plurality of chip connection pads; and the plurality of device connection pads are located in the device area, and the plurality of chip connection pads are located in the bonding area.

14. A method for manufacturing a circuit board, comprising:
providing a base substrate;
forming a first initial conductive layer on a side of the base substrate; the first initial conductive layer including a first initial main material layer and/or a first initial protective layer;
forming a first conductive layer, including: forming the first conductive layer from the first initial conductive layer using a single patterning process; wherein the first initial main material layer forms a first main material layer, and the first initial protective layer forms a first protective layer;
forming a second initial conductive layer on a side of the first conductive layer away from the base substrate; the second initial conductive layer including a second initial protective layer; and
forming a second conductive layer, including: form the second conductive layer from the second initial conductive layer using a single patterning process; wherein the second initial protective layer forms a second protective layer.

15. A light-emitting substrate, comprising the circuit board according to claim 1; and
further comprising: an electronic component, wherein pins of the electronic component are electrically connected to connection pads of the circuit board by solder.

16. The light-emitting substrate according to claim 15, further comprising: a reflective layer, wherein the reflective layer is disposed on a side of the electrical pattern away from the base substrate; the reflective layer is provided with a plurality of openings therein, and the pins of the electronic component are electrically connected to the solder and the connection pads through openings.

17. A backlight module, comprising: the light-emitting substrate according to claim 15, wherein the light-emitting substrate has a light-exit side and a non-light-exit side that are opposite; and
a plurality of optical films disposed on the light-exit side of the light-emitting substrate.

18. A display apparatus, comprising: the backlight module according to claim 17; and
further comprising a liquid crystal display panel connected to the backlight module.

19. A display panel, comprising the light-emitting substrate according to claim 15.

20. A display apparatus, comprising the display panel according to claim 19.

21. The circuit board according to claim 1, wherein
the first conductive layer further includes a first stop layer and an adhesive layer, the second conductive layer further includes a second stop layer, and a material of the adhesive layer includes any of nickel and nickel alloys; a sum of dimensions of the first stop layer, the second stop layer, the adhesive layer, the first protective layer and the second protective layer in a first direction is in a range of 0.02 μm to 2 μm, inclusive; and a dimension of any of the first stop layer, the second stop layer, the adhesive layer, the first protective layer and the second protective layer in the first direction is in a range of 100 Å to 10000 Å, inclusive; or
the first conductive layer further includes an adhesive layer, and the material of the adhesive layer includes any of molybdenum-nickel-titanium alloy, molybdenum-niobium alloy, molybdenum, titanium, molybdenum-titanium alloy, molybdenum-tungsten alloy and molybdenum-tantalum alloy; a dimension of the adhesive layer in the first direction is in a range of 200 Å to 1000 Å, inclusive; wherein
the first direction is a direction perpendicular to the base substrate and from the base substrate towards the first conductive layer.
